(19) United States
(12) Patent Application Publication
(10) Pub. No.: US 2022/0278147 A1
(43) Pub. Date: Sep. 1, 2022

(54) SOLID-STATE IMAGING DEVICE, METHOD FOR MANUFACTURING THE SAME, AND ELECTRONIC APPARATUS

(71) Applicant: SONY SEMICONDUCTOR SOLUTIONS CORPORATION, Kanagawa (JP)

(72) Inventor: Toshihiro KUROBE, Kanagawa (JP)

(73) Assignee: SONY SEMICONDUCTOR SOLUTIONS CORPORATION, Kanagawa (JP)

(21) Appl. No.: 17/631,990

(22) PCT Filed: Aug. 6, 2020
(86) PCT No.: PCT/JP2020/030118

§ 371 Date: Feb. 1, 2022

(30) Foreign Application Priority Data
Aug. 20, 2019 (JP) 2019-150215

(51) Int. Cl. H01L 27/146

(52) U.S. Cl. CPC H01L 27/14614; H01L 27/14616

(57) ABSTRACT

A solid-state imaging device includes an amplification transistor having a gate electrode including first and second vertical gate electrode portions embedded in a depth direction from a substrate surface of a semiconductor substrate. In each of the first and second vertical gate electrode portions, a second electrode width at a second depth from the substrate surface is shorter than a first electrode width at a first depth from the substrate surface. The first depth is a position of a channel top surface closest to the substrate surface of a channel region between the first and second vertical gate electrode portions. The second depth is a position of a vertical gate electrode portion bottom surface farthest from the substrate surface of the first or second vertical gate electrode portion. Directions of the first and second electrode widths are the same as a direction of a channel width of the channel region.

### TECHNICAL FIELD

The present technology relates to a solid-state imaging device, a method for manufacturing the same, and an electronic apparatus, and more particularly, to a solid-state imaging device capable of suppressing noise in a transistor structure having an embedded gate structure, a method for manufacturing the same, and an electronic apparatus.

### CROSS REFERENCE TO RELATED APPLICATIONS

This application claims the benefit of Japanese Priority Patent Application JP 2019-150215 filed on Aug. 20, 2019, the entire contents of which are incorporated herein by reference.

### BACKGROUND ART

A pixel of a complementary metal oxide semiconductor (CMOS) solid-state imaging element includes, for example, a photodiode that performs photoelectric conversion, a transfer transistor that transfers a generated charge to a floating diffusion (hereinafter, referred to as an FD), an amplification transistor that generates a signal of a voltage corresponding to a level of the charge held in the FD, and the like.

In such a CMOS solid-state imaging element, for the purpose of suppressing noise, a solid-state imaging element employing a transistor having an embedded gate structure in which a part of a gate electrode is embedded in a semiconductor substrate on which a photodiode is formed has been proposed (for example, see Patent Literatures 1 to 3).

### CITATION LIST

### Patent Literature

PTL 1: JP 2006-121093A

PTL 2: JP 2013-125862A

PTL 3: JP 2017-183636A

### SUMMARY OF INVENTION

### Technical Problem

However, there is room for improvement in a transistor having an embedded gate structure.

The present technology has been made in view of such a situation, and it is desirable to suppress noise in a transistor structure having an embedded gate structure.

### Solution to Problem

A solid-state imaging device according to a first aspect of the present technology includes: an amplification transistor having a gate electrode including first and second vertical gate electrode portions embedded in a depth direction from a substrate surface of a semiconductor substrate, in which the first vertical gate electrode portion and the second vertical gate electrode portion each have a structure so that a second electrode width at a second depth from the substrate surface is less than a first electrode width at a first depth from the substrate surface, the first depth is a position of a channel top surface closest to the substrate surface of a channel region between the first vertical gate electrode portion and the second vertical gate electrode portion, the second depth is a position of a vertical gate electrode portion bottom surface farthest from the substrate surface of the first vertical gate electrode portion and the second vertical gate electrode portion, and directions of the first electrode width and the second electrode width are the same as a direction of a channel width of the channel region.

A method for manufacturing a solid-state imaging device according to a second aspect of the present technology includes: forming, as a part of a gate electrode of an amplification transistor, first and second vertical gate electrode portions embedded in a depth direction from a substrate surface of a semiconductor substrate, in which the first vertical gate electrode portion and the second vertical gate electrode portion each have a structure so that a second electrode width at a second depth from the substrate surface is less than a first electrode width at a first depth from the substrate surface, the first depth is a position of a channel top surface closest to the substrate surface of a channel region between the first vertical gate electrode portion and the second vertical gate electrode portion, the second depth is a position of a vertical gate electrode portion bottom surface farthest from the substrate surface of the first vertical gate electrode portion and the second vertical gate electrode portion, and directions of the first electrode width and the second electrode width are the same as a direction of a channel width of the channel region.

An electronic apparatus according to a third aspect of the present technology includes: a solid-state imaging device provided with an amplification transistor having a gate electrode including first and second vertical gate electrode portions embedded in a depth direction from a substrate surface of a semiconductor substrate, in which the first vertical gate electrode portion and the second vertical gate electrode portion each have a structure so that a second electrode width at a second depth from the substrate surface is less than a first electrode width at a first depth from the substrate surface, the first depth is a position of a channel top surface closest to the substrate surface of a channel region between the first vertical gate electrode portion and the second vertical gate electrode portion, the second depth is a position of a vertical gate electrode portion bottom surface farthest from the substrate surface of the first vertical gate electrode portion and the second vertical gate electrode portion, and directions of the first electrode width and the second electrode width are the same as a direction of a channel width of the channel region.

In the first to third aspects of the present technology, the amplification transistor having the gate electrode including the first and second vertical gate electrode portions embedded in the depth direction from the substrate surface of the semiconductor substrate is provided. The first vertical gate electrode portion and the second vertical gate electrode portion each have a structure so that the second electrode width at the second depth from the substrate surface is less than the first electrode width at the first depth from the substrate surface, the first depth is the position of the channel top surface closest to the substrate surface of the channel region between the first vertical gate electrode portion and the second vertical gate electrode portion, the second depth is the position of the vertical gate electrode portion bottom surface farthest from the substrate surface of the first vertical gate electrode portion and the second vertical gate electrode portion, and the directions of the first electrode width and the second electrode width are the same as the direction of the channel width of the channel region.

The solid-state imaging device and the electronic apparatus may be independent, or may be a module incorporated in another device.

### BRIEF DESCRIPTION OF DRAWINGS

FIG. 1 is a schematic diagram illustrating a configuration example of a solid-state imaging device according to an embodiment of the present disclosure.

FIG. 2 is a circuit diagram illustrating a configuration example of a pixel unit.

FIG. 3 is a cross-sectional view of a first substrate and a second substrate.

FIGS. 4A and 4B are plan views of the second substrate and the first substrate at a predetermined position, respectively.

FIG. 5 is a cross-sectional view in a case where the pixel unit includes one substrate.

FIG. 6 is a plan view of the pixel unit at a predetermined position in FIG. 5.

FIGS. 7A to 7C are views illustrating a first configuration example of an amplification transistor.

FIGS. 8A to 8D are views illustrating a method for forming the amplification transistor according to the first configuration example.

FIGS. 9A to 9D are views illustrating the method for forming the amplification transistor according to the first configuration example.

FIG. 10 is a view showing a correspondence relationship between the amplification transistor according to the first configuration example and the plan view of FIG. 6.

FIG. 11 is a view showing a correspondence relationship between the amplification transistor according to the first configuration example and the plan view of FIG. 4A.

FIG. 12 is a plan view of the pixel unit in a case of being shared by eight sensor pixels.

FIGS. 13A to 13C are views illustrating a second configuration example of the amplification transistor.

FIGS. 14A to 14C are views illustrating a third configuration example of the amplification transistor.

FIGS. 15A to 15D are views illustrating a method for forming the amplification transistor according to the third configuration example.

FIGS. 16A and 16B are views illustrating a first modification of the third configuration example of the amplification transistor.

FIGS. 17A and 17B are views illustrating a second modification of the third configuration example of the amplification transistor.

FIGS. 18A and 18B are views illustrating a third modification of the third configuration example of the amplification transistor.

FIGS. 19A and 19B are views illustrating a method for forming the third modification of the third configuration example.

FIGS. 20A to 20C are views illustrating a fourth configuration example of the amplification transistor.

FIGS. 21A to 21D are views illustrating a method for forming the amplification transistor according to the fourth configuration example.

FIGS. 22A to 22C are views illustrating a fifth configuration example of the amplification transistor.

FIGS. 23A to 23C are views illustrating a sixth configuration example of the amplification transistor.

FIGS. 24A to 24D are views illustrating a method for forming the amplification transistor according to the sixth configuration example.

FIGS. 25A to 25C are views illustrating a seventh configuration example of the amplification transistor.

FIGS. 26A to 26D are views illustrating a method for forming the amplification transistor according to the seventh configuration example.

FIGS. 27A to 27D are views illustrating the method for forming the amplification transistor according to the seventh configuration example.

FIG. 28 is a diagram illustrating an example of use of an image sensor.

FIG. 29 is a block diagram illustrating a configuration example of an imaging apparatus as an electronic apparatus to which the present technology is applied.

### DESCRIPTION OF EMBODIMENTS

Hereinafter, an embodiment for implementing the present disclosure (hereinafter, referred to as an embodiment) will be described. Note that the description will be given in the following order.

1. Configuration example of solid-state imaging device

2. Circuit configuration example of pixel unit

3. Layered configuration example of pixel unit

4. Single-layer configuration example of pixel unit

5. First configuration example of amplification transistor

6. Second configuration example of amplification transistor

7. Third configuration example of amplification transistor

8. Modification of third configuration example of amplification transistor

9. Fourth configuration example of amplification transistor

10. Fifth configuration example of amplification transistor

11. Sixth configuration example of amplification transistor

12. Seventh configuration example of amplification transistor

13. Example of use of image sensor

14. Example of application to electronic apparatus

Note that, in the drawings referred to in the following description, the same or similar parts are denoted by the same or similar reference numerals. However, the drawings are schematic, and a relationship between a thickness and a plane dimension, a thickness ratio of each layer, and the like are different from actual ones. Further, there is a case where the drawings include portions having mutually different dimensional relationships and ratios.

Further, definitions of directions such as up and down in the following description are merely definitions for convenience of description, and do not limit a technical idea of the present disclosure. For example, when a subject is rotated by 90° and observed, top and bottom are converted to left and right and read, and when the subject is rotated by 180° and observed, the top and bottom are inverted and read.

<1. Configuration Example of Solid-State Imaging Device>

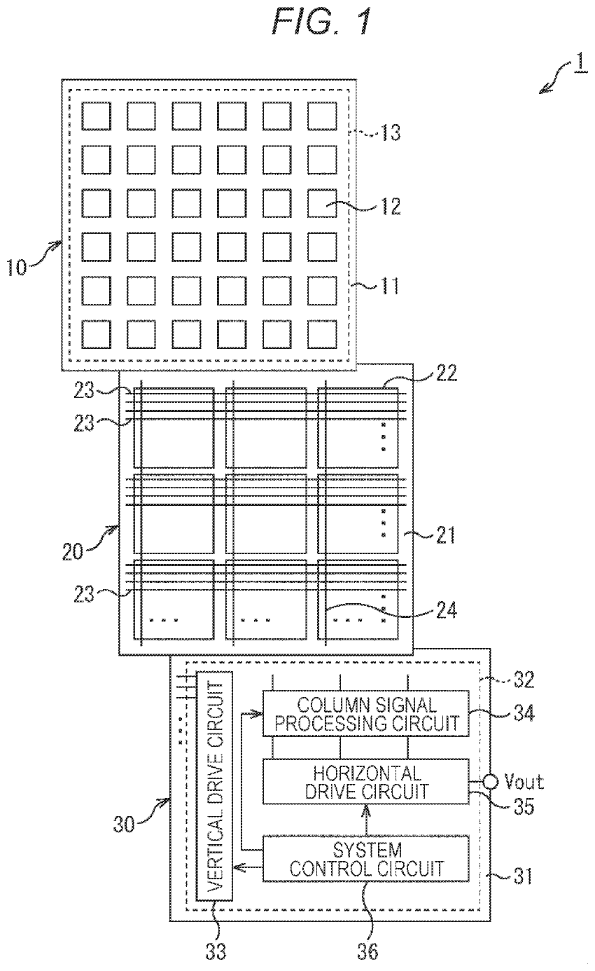

FIG. 1 is a schematic diagram illustrating a configuration example of a solid-state imaging device according to an embodiment of the present disclosure.

As shown in FIG. 1, a solid-state imaging device 1 is configured by bonding a first substrate 10, a second substrate 20, and a third substrate 30. The first substrate 10, the second substrate 20, and the third substrate 30 are stacked in this order.

The first substrate 10 has a plurality of sensor pixels 12 for performing photoelectric conversion on a first semiconductor substrate 11. The plurality of sensor pixels 12 is provided in a matrix in a pixel region 13 of the first substrate 10. The second substrate 20 has, on a second semiconductor substrate 21, a readout circuit 22 for reading out a pixel signal based on a charge output from the sensor pixel 12, one for every four sensor pixels 12. The second substrate 20 has a plurality of pixel drive lines 23 extending in a row direction and a plurality of vertical signal lines 24 extending in a column direction.

The third substrate 30 has a logic circuit 32 for processing a pixel signal on a third semiconductor substrate 31. The logic circuit 32 includes, for example, a vertical drive circuit 33, a column signal processing circuit 34, a horizontal drive circuit 35, and a system control circuit 36. The logic circuit 32 (specifically, the horizontal drive circuit 35) outputs an output voltage Vout for every sensor pixel 12 to the outside. In the logic circuit 32, for example, a low-resistance region including silicide formed using a self aligned silicide (salicide) process such as CoSi2 or NiSi may be formed on a surface of an impurity diffusion region in contact with a source electrode and a drain electrode.

The vertical drive circuit 33 sequentially selects the plurality of sensor pixels 12 in row units, for example. The column signal processing circuit 34 performs, for example, correlated double sampling (CDS) processing on a pixel signal output from each of the sensor pixels 12 in the row selected by the vertical drive circuit 33. The column signal processing circuit 34 extracts a signal level of the pixel signal by performing the CDS processing, and holds pixel data corresponding to an amount of light received by each of the sensor pixels 12, for example. The horizontal drive circuit 35 sequentially outputs, for example, the pixel data held in the column signal processing circuit 34 to the outside. The system control circuit 36 controls driving of each block (the vertical drive circuit 33, the column signal processing circuit 34, and the horizontal drive circuit 35) in the logic circuit 32, for example.

<2. Circuit Configuration Example of Pixel Unit>

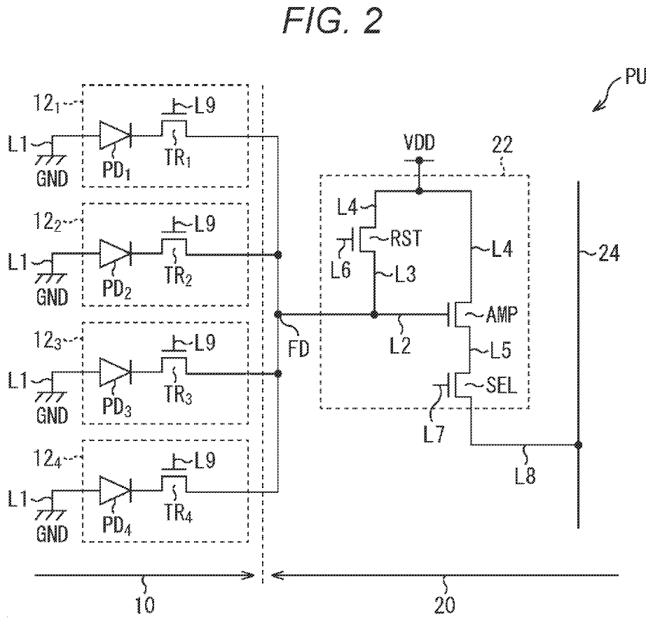

FIG. 2 is a circuit diagram illustrating a configuration example of a pixel unit PU of the solid-state imaging device 1.

One pixel unit PU includes four sensor pixels 12 and one readout circuit 22, as shown in FIG. 2. In other words, one readout circuit 22 is shared by four sensor pixels 12, and each output of four sensor pixels 12 is input to the shared readout circuit 22.

Each sensor pixel 12 has a photodiode PD that is a photoelectric conversion element and a transfer transistor TR electrically connected to the photodiode PD.

The readout circuit 22 has a floating diffusion FD, an amplification transistor AMP, a reset transistor RST, and a select transistor SEL. Note that the select transistor SEL may be omitted as necessary.

Hereinafter, in a case where four sensor pixels 12 connected to one readout circuit 22 are distinguished from each other, they are described as sensor pixels 12₁ to 12₄, as shown in FIG. 2. Similarly, the photodiodes PD and the transfer transistors TR included in the sensor pixels 12₁ to 12₄ are described as the photodiodes PD₁ to PD₄ and the transfer transistors TR₁ to TR₄. On the other hand, in a case where there is no need to distinguish four sensor pixels 12, the photodiodes PD, and the transfer transistors TR from each other, the subscripts are omitted.

The photodiode PD performs photoelectric conversion to generate a charge corresponding to an amount of received light. A cathode of the photodiode PD is electrically connected to a source of the transfer transistor TR, and an anode of the photodiode PD is electrically connected to a reference potential line (for example, ground). A drain of the transfer transistor TR is electrically connected to the floating diffusion FD, and a gate electrode of the transfer transistor TR is electrically connected to the pixel drive line 23.

An input terminal of the readout circuit 22 is the floating diffusion FD, and a source of the reset transistor RST is electrically connected to the floating diffusion FD. A predetermined power supply voltage VDD is supplied to both a drain of the reset transistor RST and a drain of the amplification transistor AMP. A gate electrode of the reset transistor RST is electrically connected to the pixel drive line 23 (FIG. 1). A source of the amplification transistor AMP is electrically connected to a drain of the select transistor SEL, and a gate electrode of the amplification transistor AMP is electrically connected to the source of the reset transistor RST. A source of the select transistor SEL is an output terminal of the readout circuit 22 and is electrically connected to the vertical signal line 24. A gate electrode of the select transistor SEL is electrically connected to the pixel drive line 23 (FIG. 1).

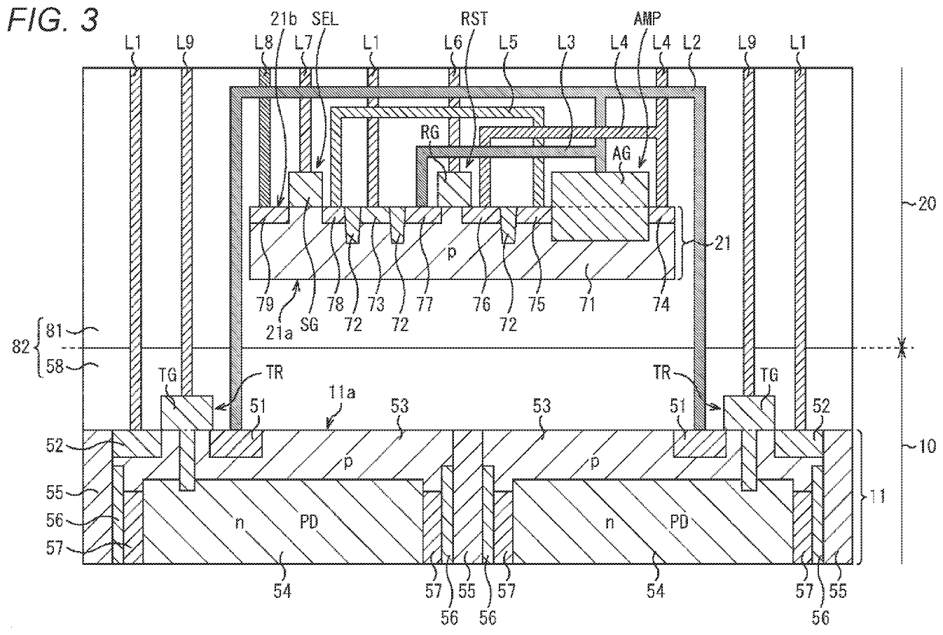

Wiring lines L1 to L9 in FIG. 2 correspond to wiring lines L1 to L9 in FIG. 3 described later.

When the transfer transistor TR is turned on in accordance with a control signal supplied to the gate electrode via the pixel drive line 23 and the wiring line L9, the transfer transistor TR transfers a charge of the photodiode PD to the floating diffusion FD. The floating diffusion FD temporarily holds the charge output from the photodiode PD via the transfer transistor TR. The reset transistor RST resets a potential of the floating diffusion FD to a predetermined potential. When the reset transistor RST is turned on, the potential of the floating diffusion FD is reset to a power supply voltage VDD.

The amplification transistor AMP generates, as a pixel signal, a signal of a voltage corresponding to the charge held in the floating diffusion FD. The amplification transistor AMP forms a source follower circuit with a load MOS (not shown) as a constant current source, and outputs a pixel signal of a voltage according to a level of the charge generated in the photodiode PD. When the select transistor SEL is turned on, the amplification transistor AMP amplifies the potential of the floating diffusion FD and outputs a pixel signal of a voltage corresponding to the potential to the column signal processing circuit 34 via the vertical signal line 24. The select transistor SEL controls an output timing of the pixel signal from the readout circuit 22. In other words, when the select transistor SEL is turned on, it is possible to output the pixel signal of the voltage corresponding to the level of the charge held in the floating diffusion FD.

The transfer transistor TR, the reset transistor RST, the amplification transistor AMP, and the select transistor SEL include, for example, an N-type metal oxide semiconductor field effect transistor (MOSFET).

<3. Layered Configuration Example of Pixel Unit>

FIG. 3 is a cross-sectional view of the first substrate 10 and the second substrate 20 on which the pixel unit PU is formed.

Note that the cross-sectional view shown in FIG. 3 is only a schematic view and is not a view intended to strictly and accurately show an actual structure. In order to clearly explain a configuration of the pixel unit PU included in the solid-state imaging device 1 on a paper surface, the cross-sectional view shown in FIG. 3 includes a portion in which horizontal positions of the transistor and an impurity diffusion layer are intentionally changed and shown.

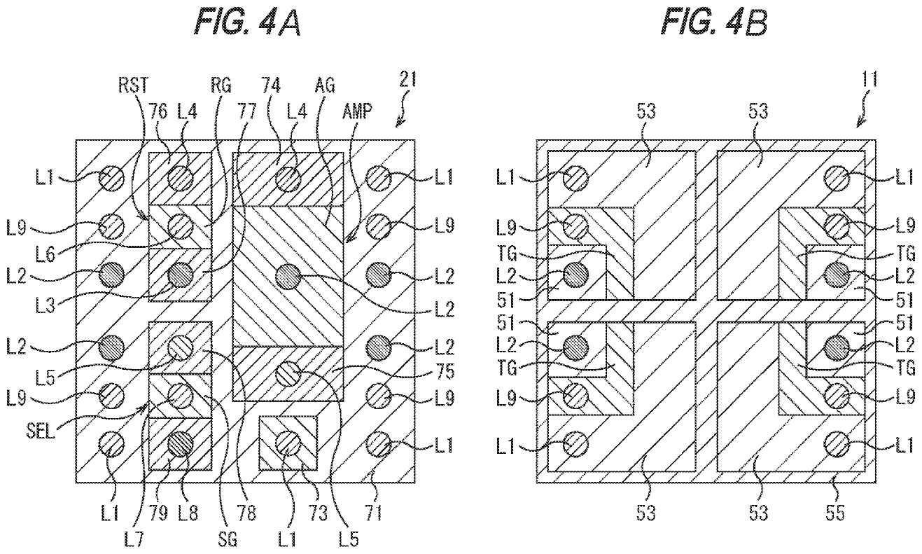

For example, in FIG. 3, a high-concentration n-type layer (n-type diffusion layer) 51 which is a part of the floating diffusion FD, a gate electrode TG of the transfer transistor TR, and a high-concentration p-type layer (p-type diffusion layer) 52 are arranged side by side in a lateral direction, but in the actual structure, there is a case where the high-concentration n-type layer 51, the gate electrode TG, and the high-concentration p-type layer 52 are arranged in a direction perpendicular to a paper surface. In this case, one of the high-concentration n-type layer 51 and the high-concentration p-type layer 52 is disposed on a front side of the paper surface with the gate electrode TG interposed therebetween, and the other of the high-concentration n-type layer 51 and the high-concentration p-type layer 52 is disposed on a back side of the paper surface. FIGS. 4A and 4B as described later show actual arrangement of the pixel unit PU more accurately.

As shown in FIG. 3, the solid-state imaging device 1 includes the first substrate 10 and the second substrate 20 that are stacked to form a stacked body. The first substrate 10 has the first semiconductor substrate 11, and the second substrate 20 is stacked on a front surface 11a side of the first semiconductor substrate 11.

On the front surface 11a side of the first semiconductor substrate 11, the transfer transistor TR is provided for every sensor pixel 12. The source of the transfer transistor TR is the high-concentration n-type layer 51, and the high-concentration n-type layers 51 provided for the sensor pixels 12 are electrically connected by the wiring line L2 to form the floating diffusion FD.

A back surface side opposite to the front surface 11a side of the first substrate 10 is a light incident surface. Therefore, the solid-state imaging device 1 is a back-illuminated solid-state imaging device, and a color filter and an on-chip lens are provided on the back surface side which is the light incident surface. The color filter and the on-chip lens are provided, for example, for every sensor pixel 12.

The first semiconductor substrate 11 included in the first substrate 10 includes, for example, a silicon substrate. A p-type layer 53 as a well layer (hereinafter, referred to as a p-well 53) is provided on a part of the front surface 11a of the first semiconductor substrate 11 and in the vicinity thereof, and an n-type layer 54 constituting the photodiode PD is provided in a region deeper than the p-well 53. The gate electrode TG of the transfer transistor TR extends from the front surface 11a of the first semiconductor substrate 11 to a depth reaching the n-type layer 54 as the photodiode PD through the p-well 53. A reference potential (for example, ground potential: 0 V) is supplied to the high-concentration p-type layer 52 as a contact portion of the p-well 53 via the wiring line L1, and a potential of the p-well 53 is set to the reference potential.

The first semiconductor substrate 11 is provided with a pixel isolation layer 55 for electrically separating adjacent sensor pixels 12 from each other. The pixel isolation layer 55 has, for example, a deep trench isolation (DTI) structure, and extends in a depth direction of the first semiconductor substrate 11. The pixel isolation layer 55 includes, for example, silicon oxide. Furthermore, in the first semiconductor substrate 11, a p-type layer 56 and an n-type layer 57 are provided between the pixel isolation layer 55 and the photodiode PD (n-type layer 54). The p-type layer 56 is formed on the pixel isolation layer 55 side, and the n-type layer 57 is formed on the photodiode PD side.

On the front surface 11a side of the first semiconductor substrate 11, an insulating film 58 is provided. The insulating film 58 is, for example, a film obtained by laminating one of a silicon oxide film (SiO), a silicon nitride film (SiN), a silicon oxynitride film (SiON), or a silicon carbonitride film (SiCN), or two or more of these.

The second semiconductor substrate 21 included in the second substrate 20 includes, for example, a silicon substrate. The second semiconductor substrate 21 has a front surface 21a facing the first substrate 10 and a back surface 21b located on an opposite side of the front surface 21a. In FIG. 3, the front surface 21a is a lower surface, and the back surface 21b is an upper surface.

The second semiconductor substrate 21 includes, for example, a p-type layer 71 as a well layer (hereinafter, referred to as a p-well 71), and the amplification transistor AMP, the select transistor SEL, and the reset transistor RST are formed on the back surface 21b side of the second semiconductor substrate 21.

An element isolation layer 72 is formed between the amplification transistor AMP and the reset transistor RST. A high-concentration p-type layer 73 as a contact portion of the p-well 71 is formed between the select transistor SEL and the reset transistor RST, and the element isolation layer 72 is also formed between the select transistor SEL and the high-concentration p-type layer 73 and between the reset transistor RST and the high-concentration p-type layer 73. The element isolation layer 72 has, for example, a shallow trench isolation (STI) structure. A reference potential (for example, ground potential: 0 V) is supplied to the high-concentration p-type layer 73 via the wiring line L1, and a potential of the p-well 71 is set to the reference potential.

The amplification transistor AMP includes a gate electrode AG, a high-concentration n-type layer 74 as the drain, and a high-concentration n-type layer 75 as the source. The gate electrode AG of the amplification transistor AMP has a structure in which a part thereof is embedded in a depth direction from a substrate surface (the back surface 21b) of the second semiconductor substrate 21.

The reset transistor RST includes a gate electrode RG, a high-concentration n-type layer 76 as the drain, and a high-concentration n-type layer 77 as the source. The select transistor SEL includes a gate electrode SG, a high-concentration n-type layer 78 as the drain, and a high-concentration n-type layer 79 as the source.

The gate electrode AG of the amplification transistor AMP is connected with the high-concentration n-type layer 51 provided for every sensor pixel 12 on the first semiconductor substrate 11 by the wiring line L2. Further, the gate electrode AG of the amplification transistor AMP is also connected to the high-concentration n-type layer 77, which is the source of the reset transistor RST, by the wiring line L3. The floating diffusion FD is constituted by the high-concentration n-type layer 51 of each sensor pixel 12 including the wiring line L2 and the high-concentration n-type layer 77 serving as the source of the reset transistor RST including the wiring line L3.

The high-concentration n-type layer 74, which is the drain of the amplification transistor AMP, and the high-concentration n-type layer 76, which is the drain of the reset transistor RST, are connected by the wiring line L4. A predetermined power supply voltage VDD is supplied to the high-concentration n-type layer 74 and the high-concentration n-type layer 76 via the wiring line L4.

The high-concentration n-type layer 75, which is the source of the amplification transistor AMP, and the high-concentration n-type layer 78, which is the drain of the select transistor SEL, are connected by the wiring line L5.

The gate electrode RG of the reset transistor RST is connected with the pixel drive line 23 via the wiring line L6, and a drive signal for controlling the reset transistor RST is supplied from the vertical drive circuit 33.

The gate electrode SG of the select transistor SEL is connected with the pixel drive line 23 via the wiring line L7, and a drive signal for controlling the select transistor SEL is supplied from the vertical drive circuit 33. The high-concentration n-type layer 79, which is the source of the select transistor SEL, is connected with the vertical signal line 24 (FIG. 2) via the wiring line L8, and a pixel signal of a voltage corresponding to the charge held in the floating diffusion FD is output to the vertical signal line 24 via the wiring line L8.

The gate electrode TG of the transfer transistor TR is connected with the pixel drive line 23 via the wiring line L9, and a drive signal for controlling the transfer transistor TR is supplied from the vertical drive circuit 33.

The second substrate 20 has an insulating film 81 that covers the front surface 21a, a part of the back surface 21b, and a side surface of the second semiconductor substrate 21. The insulating film 81 is, for example, a film obtained by laminating one of SiO, SiN, SiON, or SiCN, or two or more of these. The insulating film 58 of the first substrate 10 and the insulating film 81 of the second substrate 20 are joined to each other to form an interlayer insulating film 82.

Although any metal material can be selected as a material of the wiring line L1 to the wiring line L9, for example, a portion extending in a stacking direction of the first substrate 10 and the second substrate 20 can include tungsten (W), and a portion extending in a direction perpendicular to the stacking direction (for example, a horizontal direction) can include copper (Cu) or a Cu alloy containing Cu as a main component.

FIGS. 4A and 4B are plan views of the pixel unit PU at a predetermined position (depth) in the stacking direction of the first substrate 10 and the second substrate 20.

More specifically, FIG. 4A is a plan view of the pixel unit PU at the same position as the back surface 21b of the second semiconductor substrate 21, and FIG. 4B is a plan view of the pixel unit PU at the same position as the front surface 11a of the first semiconductor substrate 11.

As shown in FIGS. 4A and 4B, the first semiconductor substrate 11 of the first substrate 10 and the second semiconductor substrate 21 of the second substrate 20 are actually in the same size and overlap each other.

On the second semiconductor substrate 21 of the second substrate 20, a transistor group including the amplification transistor AMP, the select transistor SEL, and the reset transistor RST is arranged on a center side of the pixel unit PU in a plan view, and on an outer periphery of the transistor group, the wiring lines L1, L2, L9, etc. are arranged and penetrate in the stacking direction to electrically connect the first semiconductor substrate 11 and the second semiconductor substrate 21.

As shown in FIG. 4B, four sensor pixels 12 included in one pixel unit PU are separated by the pixel isolation layer 55 and arranged point-symmetrically with respect to the center of the pixel unit PU. In addition, the transfer transistors TR each arranged for every sensor pixel 12 on the first semiconductor substrate 11 and the high-concentration n-type layers 51 each of which is a part of the floating diffusion FD are also arranged point-symmetrically with respect to the center of the pixel unit PU.

<4. Single-Layer Configuration Example of Pixel Unit>

In the above-described example, the solid-state imaging device 1 has been described as being configured by stacking three substrates of the first substrate 10, the second substrate 20, and the third substrate 30. However, it can be formed on a single substrate instead of stacking a plurality of substrates. Alternatively, a configuration in which two substrates of the first substrate 10 and the second substrate 20 shown in FIGS. 3, 4A, and 4B are formed on one substrate can be adopted.

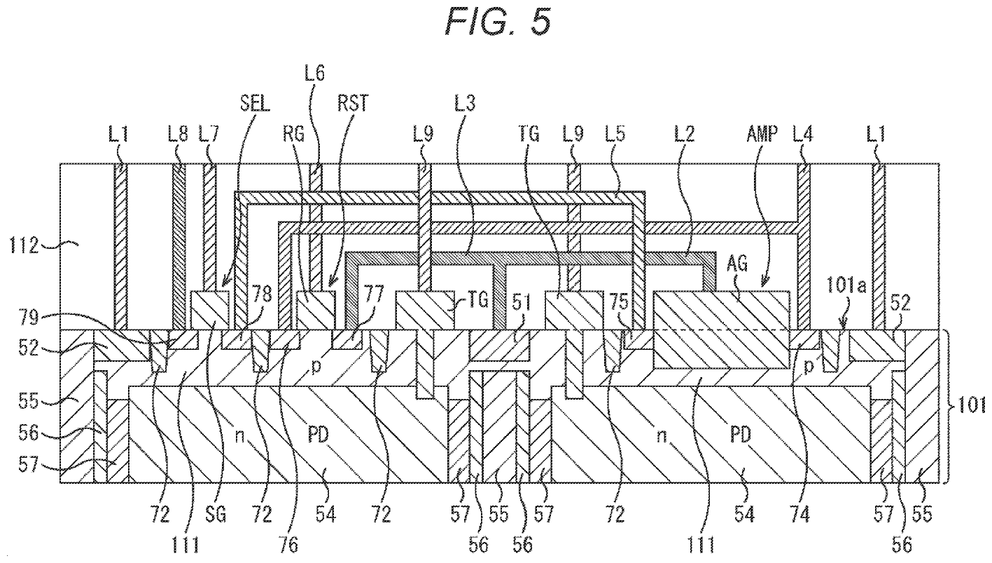

FIG. 5 is a cross-sectional view in a case where two substrates (the first substrate 10 and the second substrate 20) shown in FIGS. 3, 4A, and 4B are configured by one substrate.

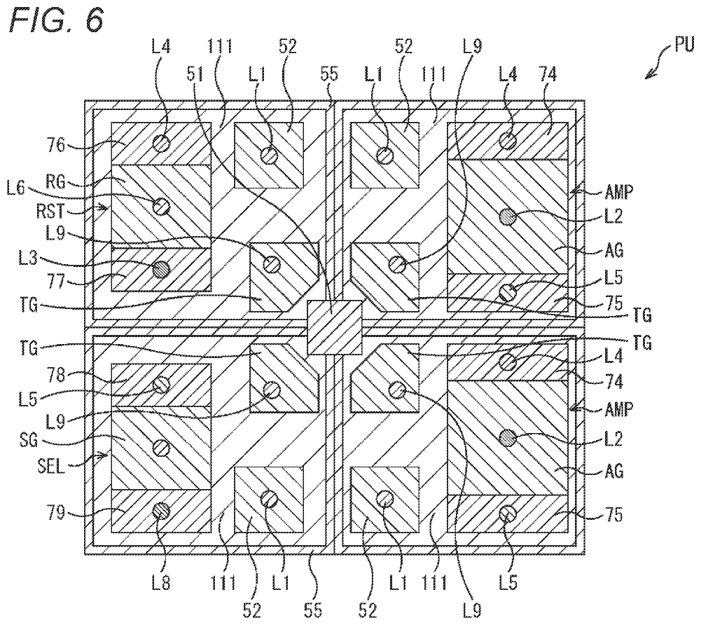

Like the cross-sectional view of FIG. 3, the cross-sectional view shown in FIG. 5 is only a schematic view and is not a view intended to strictly and accurately show an actual structure. FIG. 6 as described later shows actual arrangement of the transistor group included in the pixel unit PU more accurately.

In FIG. 5, the same reference numerals are given to portions corresponding to those in the cross-sectional view of FIG. 3, and description of the portions will be omitted as appropriate.

In FIG. 5, a semiconductor substrate 101 includes, for example, a silicon substrate. A p-type layer 111 serving as a well layer (hereinafter, referred to as a p-well 111) is provided on a part of a front surface 101a of the semiconductor substrate 101 and in the vicinity thereof, and the n-type layer 54 constituting the photodiode PD is provided in a region deeper than the p-well 111. The p-well 111 corresponds to the p-well 53 and the p-well 71 in FIG. 3.

A back surface side opposite to the front surface 101a side of the semiconductor substrate 101 is a light incident surface. On the back surface side of the semiconductor substrate 101, a color filter and an on-chip lens are provided. The color filter and the on-chip lens are provided, for example, for every sensor pixel 12.

On the front surface 101a side of the semiconductor substrate 101, the amplification transistor AMP, the reset transistor RST, the select transistor SEL, and the transfer transistor TR are formed. Since these details are similar to those in FIG. 3, description thereof is omitted. The gate electrode AG of the amplification transistor AMP has a structure in which a part thereof is embedded in a depth direction from a substrate surface (the front surface 101a) of the semiconductor substrate 101. An upper surface of the transistor group such as the amplification transistor AMP and the reset transistor RST is covered with an insulating film 112.

FIG. 6 is a plan view of the pixel unit PU at a position (depth) of the front surface 101a of the semiconductor substrate 101.

One pixel unit PU is configured by arranging the sensor pixels 12 in 2×2 arrangement. In a center of the pixel unit PU, the high-concentration n-type layer 51 as the floating diffusion FD shared by four sensor pixels 12 is arranged. The transfer transistor TR is arranged near the floating diffusion FD of each sensor pixel 12.

Of four sensor pixels 12 constituting one pixel unit PU, one sensor pixel 12 is provided with the reset transistor RST, another sensor pixel 12 is provided with the select transistor SEL, and remaining two sensor pixels 12 are each provided with the amplification transistor AMP. The gate electrodes AG of the amplification transistors AMP arranged in two sensor pixels 12 are connected to each other by the wiring line L2, the high-concentration n-type layers 74 as the drains are connected to each other by the wiring line L4, and the high-concentration n-type layers 75 as the sources are connected to each other by the wiring line L5, so that they operate as one amplification transistor AMP.

In the sensor pixel 12 of the pixel unit PU configured as described above, as shown in FIGS. 3 and 5, a part of the gate electrode AG of the amplification transistor AMP is embedded in the depth direction from the substrate surface. With such a structure, noise is suppressed more than in a planar transistor having a flat gate electrode. Hereinafter, a structure of the amplification transistor AMP that is a part of the sensor pixel 12 of the solid-state imaging device 1 will be described in more detail.

<5. First Configuration Example of Amplification Transistor>

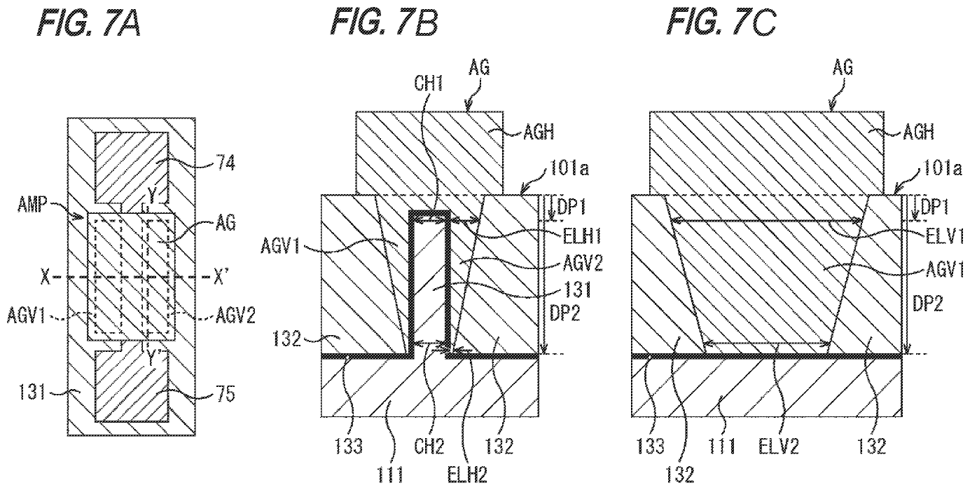

FIGS. 7A to 7C show a first configuration example of the amplification transistor AMP.

FIG. 7A is a plan view of the amplification transistor AMP, FIG. 7B is a cross-sectional view taken along a line X-X′ of FIG. 7A, and FIG. 7C is a cross-sectional view taken along a line Y-Y′ of FIG. 7A.

In FIGS. 7A to 7C, the same reference numerals are given to portions corresponding to those in FIG. 5, and description of the portions will be omitted as appropriate.

In the plan view of FIG. 7A, the gate electrode AG of the amplification transistor AMP is disposed between the high-concentration n-type layer 74 as the drain and the high-concentration n-type layer 75 as the source.

As shown in FIGS. 7B and 7C, the gate electrode AG of the amplification transistor AMP includes a flat electrode portion AGH above the front surface 101a (substrate surface) of the semiconductor substrate 101 and first and second vertical gate electrode portions AGV1 and AGV2 embedded in the depth direction from the substrate surface. In a case where the first vertical gate electrode portion AGV1 and the second vertical gate electrode portion AGV2 are not particularly distinguished, they are simply referred to as a vertical gate electrode portion AGV.

In the cross-sectional view of FIG. 7B, between the first vertical gate electrode portion AGV1 and the second vertical gate electrode portion AGV2, a fin portion 131 serving as a channel region of the amplification transistor AMP is formed by the p-well 111. Note that the fin portion 131 is formed by the p-well 111 in the first configuration example, but there is also a case where the fin portion 131 is a region of a semiconductor substrate where ions are not implanted.

Outer sides of the first and second vertical gate electrode portions AGV1 and AGV2 are surrounded by an insulating film 132 including an oxide film. An oxide film 133 functioning as a gate oxide film of the amplification transistor AMP is formed between the fin portion 131 serving as the channel region and the first and second vertical gate electrode portions AGV1 and AGV2. The oxide film 133 is also formed between the insulating film 132 and the p-well 111.

In the cross-sectional view of FIG. 7B, the first and second vertical gate electrode portions AGV1 and AGV2 each have structure in which a second electrode width ELH2 at a second depth DP2 from the front surface 101a is less than a first electrode width ELH1 at a first depth DP1 from the front surface 101a. In other words, the first vertical gate electrode portion AGV1 and the second vertical gate electrode portion AGV2 each have a reverse tapered shape where a bottom surface side of the vertical gate electrode portion AGV is narrow in the cross-sectional view.

On the other hand, with respect to the fin portion 131 serving as the channel region, a first channel width CH1 at the first depth DP1 from the front surface 101a and a second channel width CH2 at the second depth DP2 from the substrate surface are the same or substantially the same. Here, “substantially the same” indicates a range of a difference that can be regarded as the same, and includes a deviation and the like due to a manufacturing error or the like.

Here, the first depth DP1 is a position of a channel top surface closest to the front surface 101a of the fin portion 131 provided between the first vertical gate electrode portion AGV1 and the second vertical gate electrode portion AGV2, and the second depth DP2 is a position of a bottom surface of the vertical gate electrode portion AGV farthest from the front surface 101a of the first vertical gate electrode portion AGV1 and the second vertical gate electrode portion AGV2. Note that, in the drawings, the positions are slightly shifted to give priority to visibility (similarly applied to other drawings described later).

Also in the cross-sectional view of FIG. 7C, each of the first and second vertical gate electrode portions AGV1 and AGV2 has a structure in which a second electrode width ELV2 at the second depth DP2 from the front surface 101a is less than a first electrode width ELV1 at the first depth DP1 from the front surface 101a. In other words, the first vertical gate electrode portion AGV1 and the second vertical gate electrode portion AGV2 each have a reverse tapered shape where the bottom surface side of the vertical gate electrode portion AGV is narrow in the cross-sectional view.

As described above, the amplification transistor AMP has a FinFET structure in which the fin portion 131 forming the channel region is sandwiched between the first vertical gate electrode portion AGV1 and the second vertical gate electrode portion AGV2 embedded in the depth direction from the front surface 101a (substrate surface) of the semiconductor substrate 101.

Each of the first and second vertical gate electrode portions AGV1 and AGV2 has the reverse tapered shape with the narrow bottom surface side, and a contact area with the p-well 111 is reduced, so that a parasitic capacitance can be reduced. Since the parasitic capacitance can be reduced, noise generated in the amplification transistor AMP can be reduced, and an SN ratio can be improved.

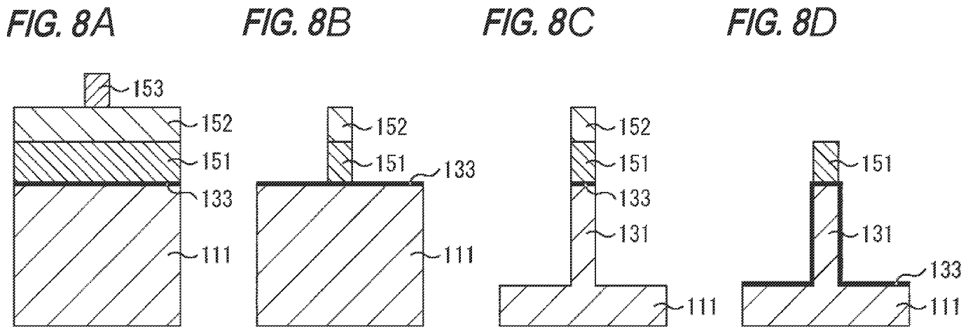

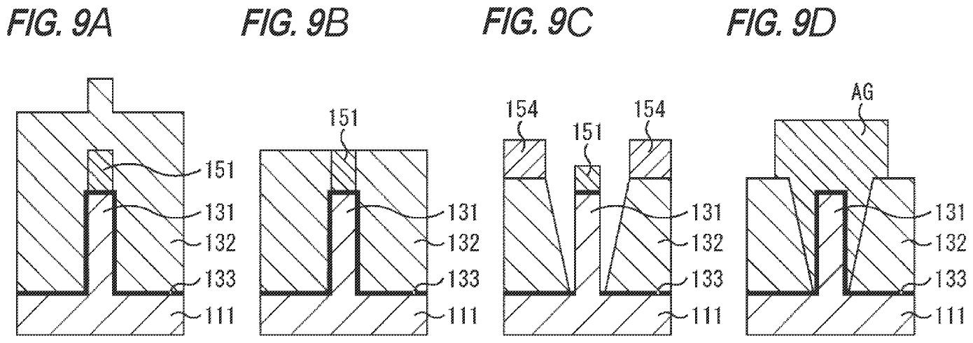

A method for forming the amplification transistor AMP according to the first configuration example shown in FIGS. 7A to 7C will be described with reference to FIGS. 8A to 8D and 9A to 9D.

As shown in FIG. 8A, after an insulating film 151, an oxide film 152, and a resist 153 are formed in this order on the oxide film 133 on the p-well 111, the resist 153 is patterned corresponding to a position of the fin portion 131. The insulating film 151 is formed as a hard mask, and can employ, for example, a silicon nitride film (SiN) or a low dielectric constant insulating film (hereinafter, referred to as a low-k insulating film) such as SiOC.

Then, as shown in FIG. 8B, after the insulating film 151 and the oxide film 152 are etched according to the pattern of the resist 153, the resist 153 is removed.

Next, as shown in FIG. 8C, the oxide film 133 and the p-well 111 are etched to a predetermined depth using the oxide film 152 as a mask, and then, as shown in FIG. 8D, the oxide film 133 is formed on a surface of the p-well 111 by thermal oxidation.

Next, as shown in FIG. 9A, after the insulating film 132 is added on the oxide film 133 by, for example, a chemical vapor deposition (CVD) method, the insulating film 132 is planarized by chemical mechanical polishing (CMP), as shown in FIG. 9B. At this time, the insulating film 151 functions as a CMP stopper.

Next, as shown in FIG. 9C, using a patterned resist 154, the insulating film 132 on each side of the fin portion 131 is etched into a reverse tapered shape.

Then, as shown in FIG. 9D, after the oxide film 133 is formed on a side surface of the fin portion 131, the insulating film 151 and the resist 154 are removed. Finally, the gate electrode AG including the flat electrode portion AGH and the first and second vertical gate electrode portions AGV1 and AGV2 is formed by using, for example, the CVD method. As a material of the gate electrode AG, for example, polysilicon is used.

Note that in the above-described steps, although the fin portion 131 is formed in two steps of etching the oxide film 152 and the insulating film 151 using the resist 153 as the mask (FIG. 8B) and of etching the oxide film 133 and the p-well 111 using the oxide film 152 as the mask (FIG. 8C), the fin portion 131 may be formed by etching to the p-well 111 by one etching using the resist 153 as a mask.

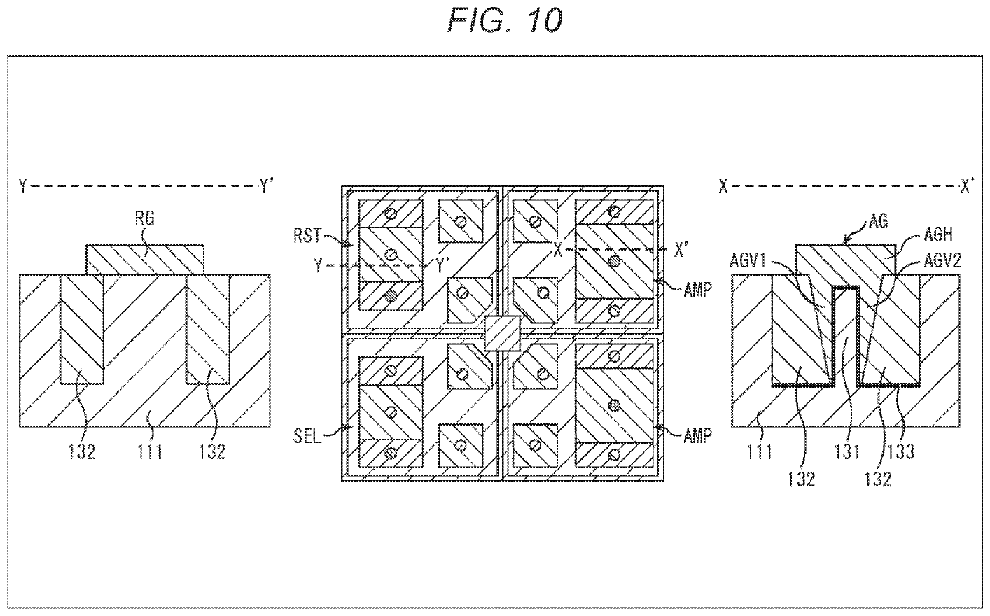

FIG. 10 shows a correspondence relationship between the amplification transistor AMP according to the first configuration example and plane arrangement of the pixel unit PU shown in FIG. 6.

In FIG. 10, a cross-sectional view of the amplification transistor AMP along a line X-X′ and a cross-sectional view of the reset transistor RST along a line Y-Y′ in the plane arrangement of the pixel unit PU shown in FIG. 6 are shown.

As shown in FIG. 10, the amplification transistor AMP has a structure in which the first and second vertical gate electrode portions AGV1 and AGV2, which are parts of the gate electrode AG, are embedded in the depth direction from the substrate surface.

On the other hand, the reset transistor RST, which is a transistor other than the amplification transistor AMP, has a structure in which the gate electrode RG is formed only on the substrate surface and is not embedded in the depth direction from the substrate surface.

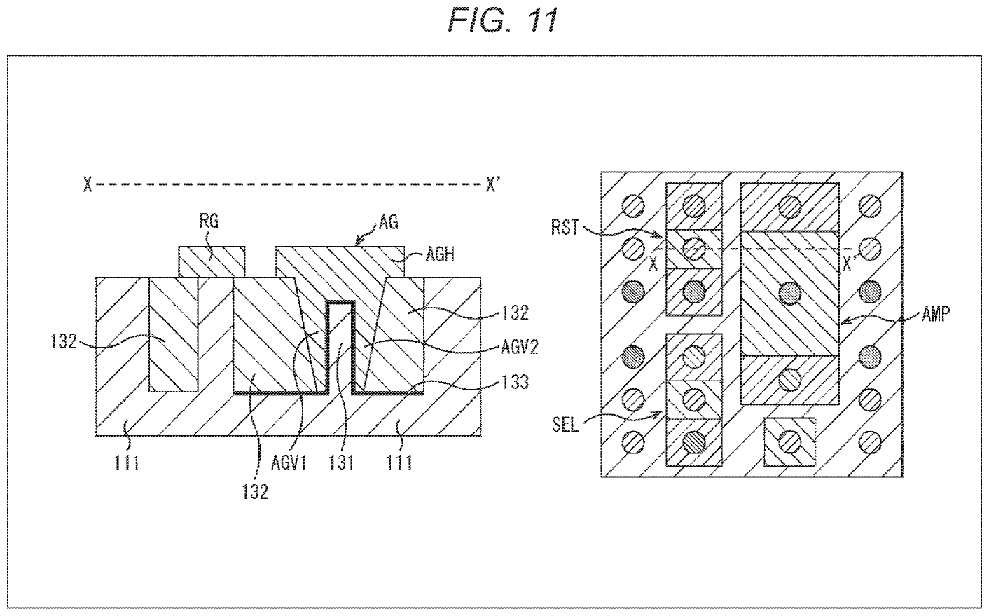

FIG. 11 shows a correspondence relationship between the amplification transistor AMP according to the first configuration example and plane arrangement of the pixel unit PU shown in FIG. 4A.

FIG. 11 is a cross-sectional view of the amplification transistor AMP and the reset transistor RST taken along a line X-X′ in the plane arrangement of the pixel unit PU shown in FIG. 4A.

Also in FIG. 11, the amplification transistor AMP has a structure in which the first and second vertical gate electrode portions AGV1 and AGV2, which are parts of the gate electrode AG, are embedded in the depth direction from the substrate surface.

On the other hand, the reset transistor RST, which is a transistor other than the amplification transistor AMP, has a structure in which the gate electrode RG is formed only on the substrate surface and is not embedded in the depth direction from the substrate surface.

The pixel unit PU of FIGS. 2, 4A and 4B, and 6 has a circuit configuration in which one readout circuit 22 is shared by four sensor pixels 12, but, for example, a circuit configuration in which one readout circuit 22 is shared by eight sensor pixels 12 is also possible.

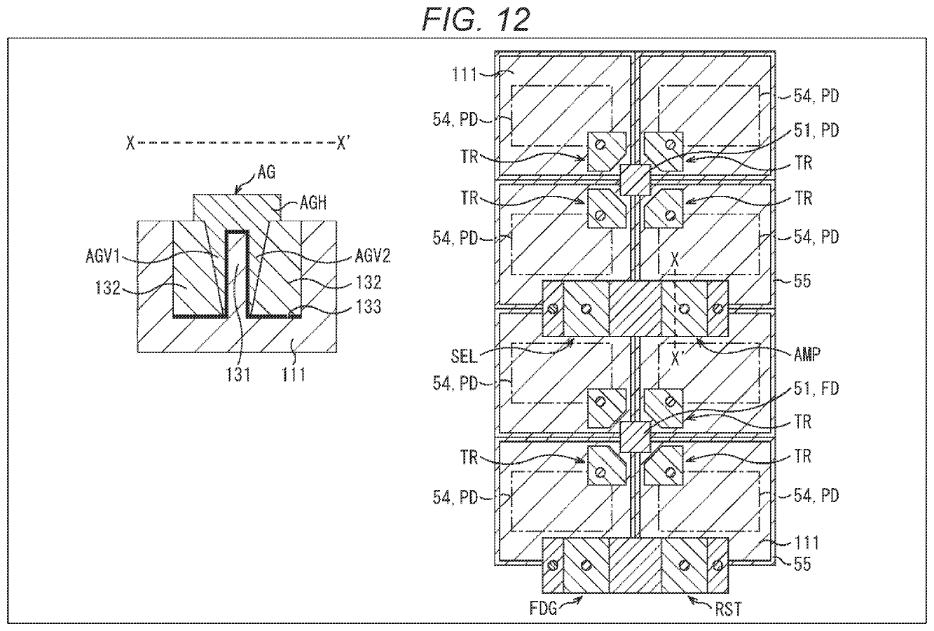

In FIG. 12, a plan view of the pixel unit PU and a cross-sectional view of the amplification transistor AMP in a case where the pixel unit PU includes one readout circuit 22 and eight sensor pixels 12 are shown.

In a case where the pixel unit PU includes one readout circuit 22 and eight sensor pixels 12, eight sensor pixels 12 are arranged in 4×2 arrangement having four in a vertical direction and two in a horizontal direction, for example. Then, the amplification transistor AMP, the reset transistor RST, the select transistor SEL, and a switching transistor FDG are arranged between the sensor pixels 12 in 2×2 units in the vertical direction. Note that the switching transistor FDG is a transistor that switches a capacitance in a case where a configuration capable of switching a capacitance of the floating diffusion FD is employed.

FIG. 12 also includes a cross-sectional view of the amplification transistor AMP taken along a line X-X′ in plane arrangement of the pixel unit PU.

Also in FIG. 12, the amplification transistor AMP has a structure in which the first and second vertical gate electrode portions AGV1 and AGV2, which are parts of the gate electrode AG, are embedded in the depth direction from the substrate surface.

<6. Second Configuration Example of Amplification Transistor>

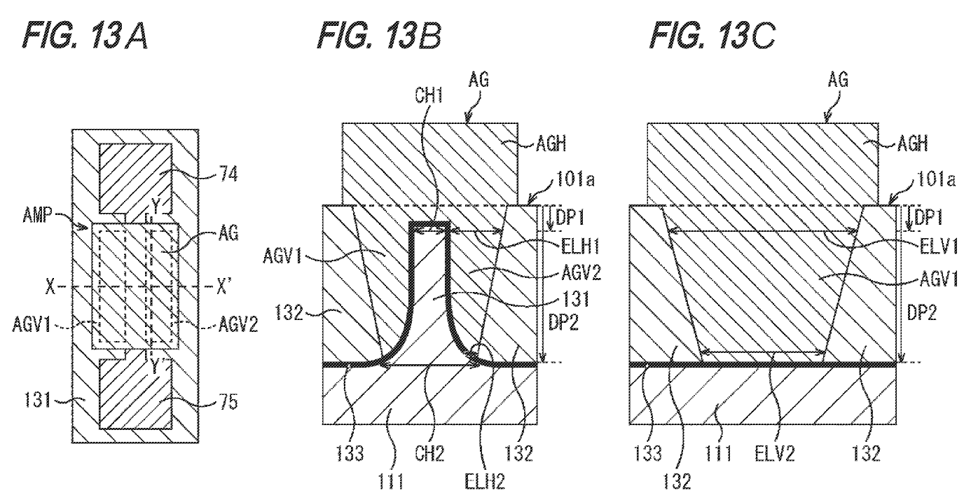

FIGS. 13A to 13C show a second configuration example of the amplification transistor AMP.

FIG. 13A is a plan view of the amplification transistor AMP, FIG. 13B is a cross-sectional view taken along a line X-X′ of FIG. 13A, and FIG. 13C is a cross-sectional view taken along a line Y-Y′ of FIG. 13A.

In FIGS. 13A to 13C, portions corresponding to those in the first configuration example shown in FIGS. 7A to 7C are denoted by the same reference numerals, and description of those portions will be omitted as appropriate.

The amplification transistor AMP according to the second configuration example shown in FIGS. 13A to 13C differs from that in the first configuration example shown in FIGS. 7A to 7C in a shape of the fin portion 131 forming the channel region, and the other points are common to those in the first configuration example shown in FIGS. 7A to 7C.

Specifically, in the first configuration example shown in FIGS. 7A to 7C, the fin portion 131 forming the channel region of the amplification transistor AMP is formed such that the first channel width CH1 at the first depth DP1 and the second channel width CH2 at the second depth DP2 are the same or substantially the same.

On the other hand, in the second configuration example of FIGS. 13A to 13C, in the cross-sectional view of FIG. 13B, a side surface closer to a bottom of the fin portion 131 far from the front surface 101a has a rounded shape (curved shape). Thus, the first channel width CH1 at the first depth DP1 is less than the second channel width CH2 at the second depth DP2.

In both the cross-sectional views of FIGS. 13B and 13C, the first vertical gate electrode portion AGV1 and the second vertical gate electrode portion AGV2 each have a reverse tapered shape having a narrow bottom surface side. This is similar to the first configuration example shown in FIGS. 7B and 7C.

Also in the amplification transistor AMP according to the second configuration example shown in FIGS. 13A to 13C, since each of the first and second vertical gate electrode portions AGV1 and AGV2 has the reverse tapered shape having the narrow bottom surface side and a contact area with the p-well 111 is reduced, a parasitic capacitance can be reduced. Since the parasitic capacitance can be reduced, noise generated in the amplification transistor AMP can be reduced, and an SN ratio can be improved.

<7. Third Configuration Example of Amplification Transistor>

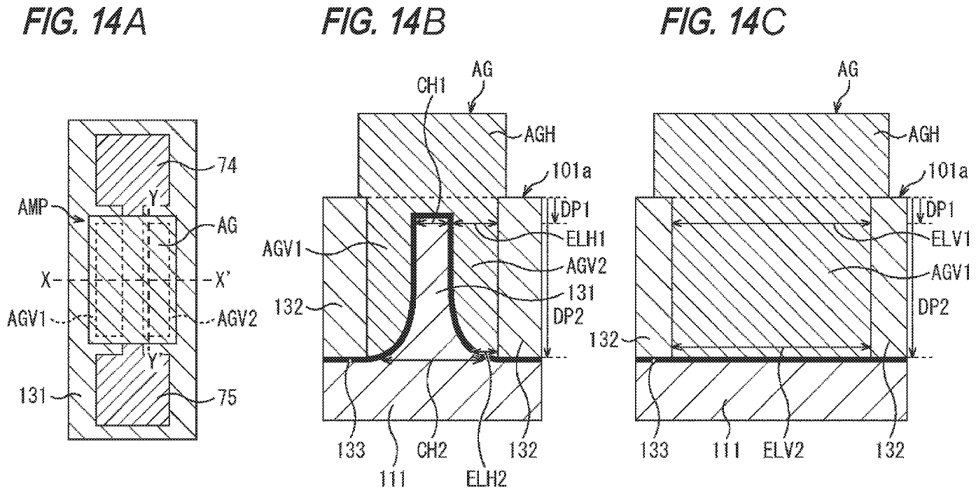

FIGS. 14A to 14C show a third configuration example of the amplification transistor AMP.

FIG. 14A is a plan view of the amplification transistor AMP, FIG. 14B is a cross-sectional view taken along a line X-X′ of FIG. 14A, and FIG. 14C is a cross-sectional view taken along a line Y-Y′ of FIG. 14A.

In FIGS. 14A to 14C, the same reference numerals are given to portions corresponding to those in the first configuration example and the second configuration example described above, and description of those portions will be omitted as appropriate.

The amplification transistor AMP according to the third configuration example shown in FIGS. 14A to 14C is different from that in the second configuration example shown in FIGS. 13A to 13C in shapes of the first and second vertical gate electrode portions AGV1 and AGV2, and the other points are common to those in the second configuration example shown in FIGS. 13A to 13C.

Specifically, in the second configuration example shown in FIGS. 13A to 13C, the first vertical gate electrode portion AGV1 and the second vertical gate electrode portion AGV2 are each formed into the reverse tapered shape with the narrow bottom surface side in both the cross-sectional views of FIGS. 13B and 13C.

On the other hand, in the third configuration example of FIGS. 14A to 14C, a boundary surface between the first vertical gate electrode portion AGV1 or the second vertical gate electrode portion AGV2 and the insulating film 132 is formed perpendicular to the front surface 101a (substrate surface) of the semiconductor substrate 101 in both the cross-sectional views of FIGS. 14B and 14C.

The first electrode width ELV1 at the first depth DP1 and the second electrode width ELV2 at the second depth DP2 of each of the first and second vertical gate electrode portions AGV1 and AGV2 in the cross-sectional view of FIG. 14C are the same or substantially the same.

On the other hand, regarding a relationship between the first electrode width ELH1 at the first depth DP1 and the second electrode width ELH2 at the second depth DP2 of each of the first and second vertical gate electrode portions AGV1 and AGV2 in the cross-sectional view of FIG. 14B, a bottom side surface of the fin portion 131 has a rounded structure, so that the second electrode width ELH2 at the second depth DP2 is less than the first electrode width ELH1 at the first depth DP1.

Accordingly, also in the amplification transistor AMP according to the third configuration example shown in FIGS. 14A to 14C, each of the first and second vertical gate electrode portions AGV1 and AGV2 has a shape with a narrow bottom surface side and a contact area with the p-well 111 is reduced, so that a parasitic capacitance can be reduced. Since the parasitic capacitance can be reduced, noise generated in the amplification transistor AMP can be reduced, and an SN ratio can be improved.

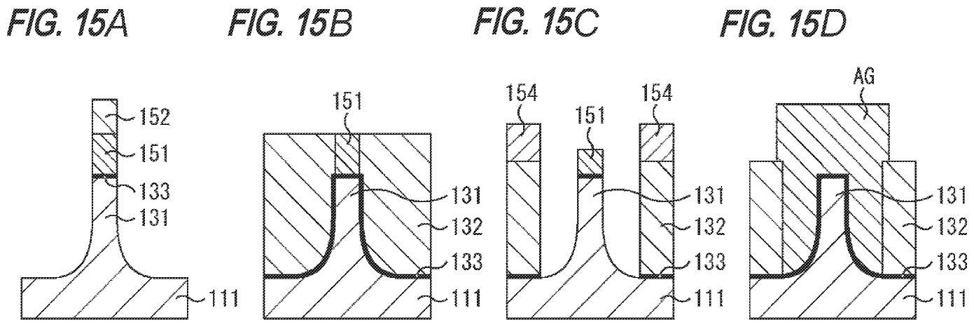

A method for forming the amplification transistor AMP according to the third configuration example shown in FIGS. 14A to 14C will be described with reference to FIGS. 15A to 15D.

FIGS. 15A to 15D illustrating the formation method of the third configuration example correspond to drawings in which some of the common steps in the formation method of the first configuration example shown in FIGS. 8A to 8D and 9A to 9D are omitted. FIG. 15A corresponds to FIG. 8C, and FIG. 15B corresponds to FIG. 9B. FIG. 15C corresponds to FIG. 9C, and FIG. 15D corresponds to FIG. 9D.

After the steps of FIGS. 8A and 8B are performed, as shown in FIG. 15A, the oxide film 133 and the p-well 111 are etched from the substrate surface to a predetermined depth using the oxide film 152 as a mask. By adjusting process conditions such as a gas type, bias voltage, power, and processing time in dry etching, the side surface of the fin portion 131 can be formed in a rounded shape, as shown in FIG. 15A. Further, the rounded shape of the side surface of the fin portion 131 includes a case where it is formed unintentionally.

Thereafter, as shown in FIG. 15B, the added insulating film 132 is planarized by CMP using the insulating film 151 as a stopper.

Thereafter, as shown in FIG. 15C, the insulating film 132 on each side of the fin portion 131 is etched in a direction perpendicular to the substrate surface by anisotropic etching using the patterned resist 154.

Then, as shown in FIG. 15D, after the oxide film 133 is formed on the side surface of the fin portion 131, the insulating film 151 and the resist 154 are removed. Finally, the gate electrode AG including the first and second vertical gate electrode portions AGV1 and AGV2 is formed by using, for example, a CVD method. As a material of the gate electrode AG, for example, polysilicon is used.

In the above-described steps, the step of etching the oxide film 152 and the insulating film 151 on the upper surface of the p-well 111 and the step of etching the oxide film 133 and the p-well 111 may be performed in one etching step. This is similar to the formation method of the first configuration example.

<8. Modification of Third Configuration Example of Amplification Transistor>

### First Modification

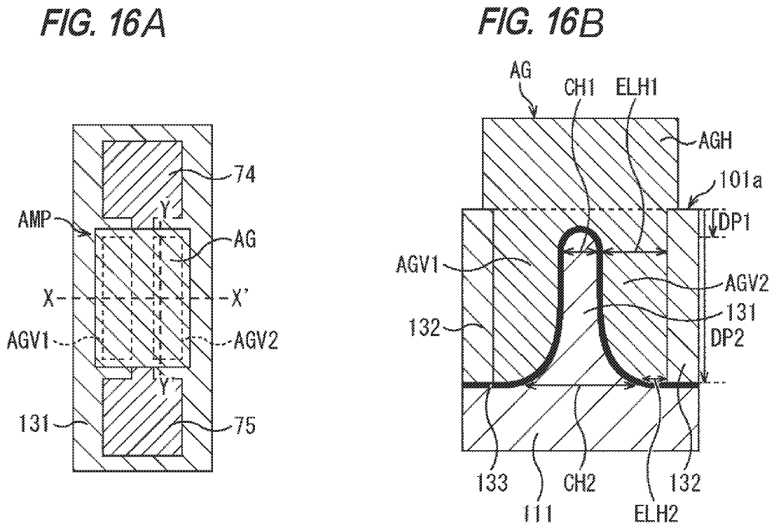

FIGS. 16A and 16B show a first modification of the amplification transistor AMP according to the third configuration example shown in FIGS. 14A to 14C.

FIG. 16A is a plan view of the amplification transistor AMP, and FIG. 16B is a cross-sectional view taken along a line X-X′ of FIG. 16A. A cross-sectional view taken along a line Y-Y′ of FIG. 16A will be omitted because it is similar to that of FIG. 14C.

The amplification transistor AMP according to the first modification shown in FIGS. 16A and 16B differs from that in the third configuration example shown in FIGS. 14A to 14C in a shape of the fin portion 131 forming the channel region, and the other points are common to those in the third configuration example shown in FIGS. 14A to 14C.

Specifically, in the first modification shown in FIGS. 16A and 16B, a side surface of a channel top surface near the front surface 101a of the fin portion 131 has a rounded structure. The rounded shape of the channel top surface can be formed by adjusting a thickness of the insulating film 151 in FIGS. 15A to 15C and the process conditions in the dry etching. Alternatively, the rounded shape of the channel top surface may be formed unintentionally. When a corner is formed on the channel top surface, an interface state density is deteriorated, and electrons as carriers are easily captured. Therefore, by adopting the rounded shape, the number of electrons captured in the interface state can be reduced.

Also in the amplification transistor AMP according to the first modification shown in FIGS. 16A and 16B, each of the first and second vertical gate electrode portions AGV1 and AGV2 has a shape with a narrow bottom surface side and a contact area with the p-well 111 is reduced, so that a parasitic capacitance can be reduced. Since the parasitic capacitance can be reduced, noise generated in the amplification transistor AMP can be reduced, and an SN ratio can be improved.

### Second Modification

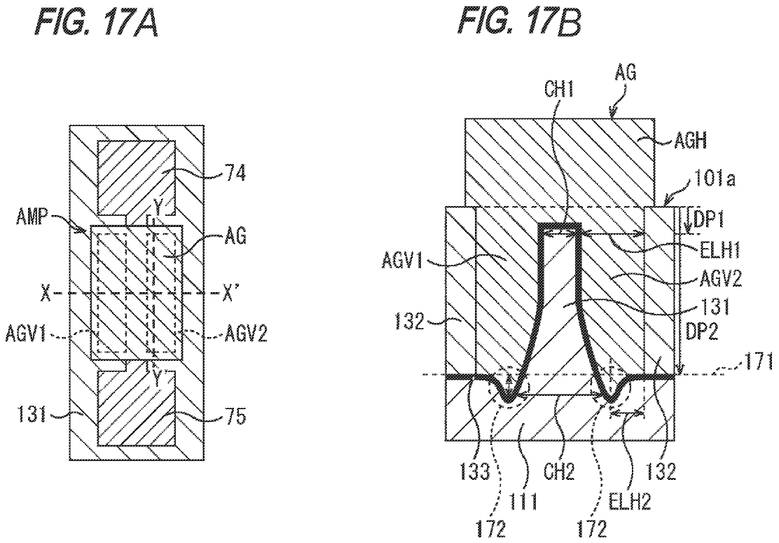

FIGS. 17A and 17B show a second modification of the amplification transistor AMP according to the third configuration example shown in FIGS. 14A to 14C.

FIG. 17A is a plan view of the amplification transistor AMP, and FIG. 17B is a cross-sectional view taken along a line X-X′ of FIG. 17A. A cross-sectional view taken along a line Y-Y′ of FIG. 17A will be omitted because of similarity to that of FIG. 14C.

The amplification transistor AMP according to the second modification shown in FIGS. 17A and 17B is different from that in the third configuration example shown in FIGS. 14A to 14C in shapes of the fin portion 131 forming the channel region and the first and second vertical gate electrode portions AGV1 and AGV2, and the other points are common to those in the third configuration example shown in FIGS. 14A to 14C.

Specifically, in the second modification shown in FIGS. 17A and 17B, the first and second vertical gate electrode portions AGV1 and AGV2 each have a sub-trench 172, as shown in the cross-sectional view of FIG. 17B.

In each of the first and second vertical gate electrode portions AGV1 and AGV2, the sub-trench 172 is formed by digging an inner side wall on the fin portion 131 side to a position deeper than an outer side wall in the cross-sectional view of FIG. 17B. The inner side wall is located deeper than a contact surface 171 where the insulating film 132 and the p-well 111 are in contact via the oxide film 133. Therefore, a contact area between fin portion 131 and vertical gate electrode portion AGV increases, so that a drain current flowing through the channel region can be increased. Thereby, transconductance gₘ can be increased. By increasing the transconductance gₘ, noise can be reduced, and an SN ratio can be improved.

Also in the amplification transistor AMP according to the second modification shown in FIGS. 17A and 17B, since the first and second vertical gate electrode portions AGV1 and AGV2 each have a shape with a narrow bottom surface side, a parasitic capacitance can be reduced. Since the parasitic capacitance can be reduced, noise generated in the amplification transistor AMP can be reduced, and an SN ratio can be improved.

### Third Modification

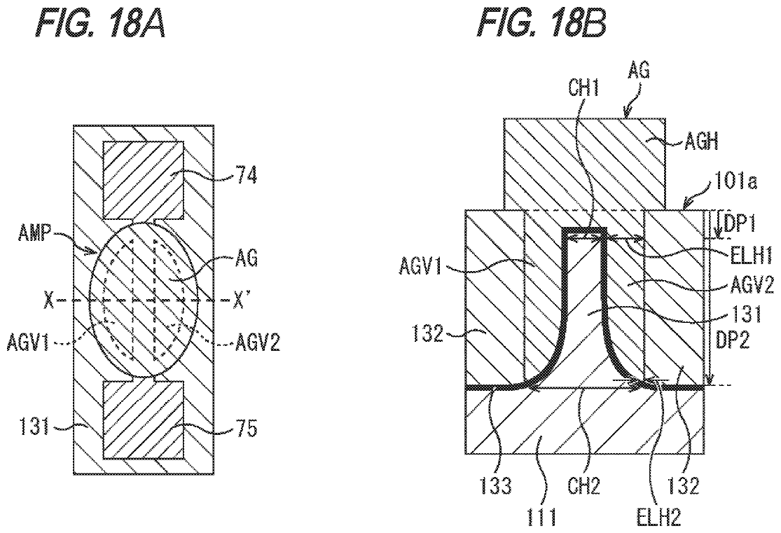

FIGS. 18A and 18B show a third modification of the amplification transistor AMP according to the third configuration example shown in FIGS. 14A to 14C.

FIG. 18A is a plan view of the amplification transistor AMP, and FIG. 18B is a cross-sectional view taken along a line X-X′ of FIG. 18A.

The amplification transistor AMP according to the third modification shown in FIGS. 18A and 18B differs from that in the third configuration example shown in FIGS. 14A to 14C in a shape of the gate electrode AG, and the other points are common to those in the third configuration example shown in FIGS. 14A to 14C.

Specifically, in the third configuration example shown in FIGS. 14A to 14C, a plane shape of the flat electrode portion AGH, which is the portion above the substrate surface (front surface 101a) of the gate electrode AG, is rectangular.

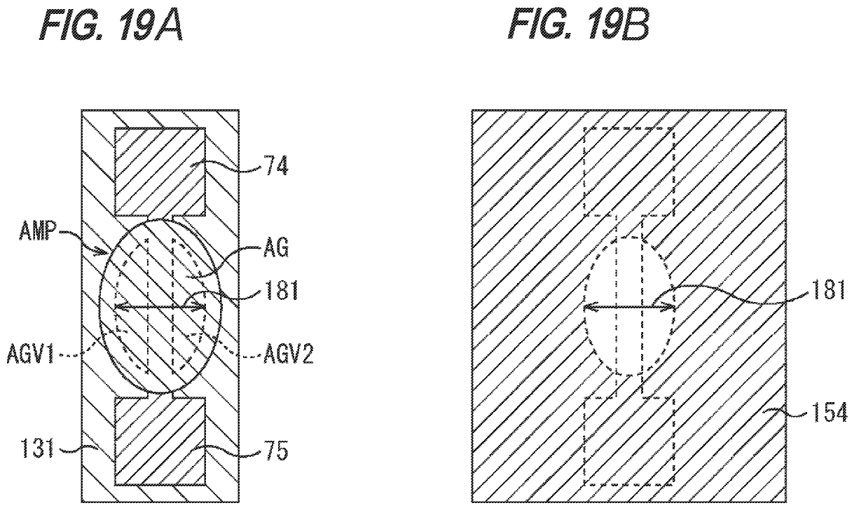

On the other hand, in the third modification shown in FIGS. 18A and 18B, as shown in the plan view of FIG. 18A, a plane shape of the flat electrode portion AGH is elliptical. Such an elliptical flat electrode portion AGH can be realized by patterning a plane shape of the resist 154 in the step shown in FIG. 9C into an elliptical shape as shown in FIG. 19B. A diameter 181 in a minor axis direction of an elliptical pattern of the resist 154 corresponds to a width of the gate electrode AG at a position of the substrate surface (front surface 101a), as shown in FIG. 19A.

Each of the first and second vertical gate electrode portions AGV1 and AGV2 of a cross section in a direction perpendicular to the line X-X′ of FIG. 18A may be formed such that, as shown in FIG. 14C, the first electrode width ELV1 at the first depth DP1 and the second electrode width ELV2 at the second depth DP2 are the same or substantially the same. Alternatively, as shown in FIG. 7C, it may be formed in a reverse tapered shape where the bottom surface side of the vertical gate electrode portion AGV is narrow.

Also in the amplification transistor AMP according to the third modification shown in FIGS. 18A and 18B, since the first and second vertical gate electrode portions AGV1 and AGV2 each have a shape with a narrow bottom surface side, a parasitic capacitance can be reduced. Since the parasitic capacitance can be reduced, noise generated in the amplification transistor AMP can be reduced, and an SN ratio can be improved.

<9. Fourth Configuration Example of Amplification Transistor>

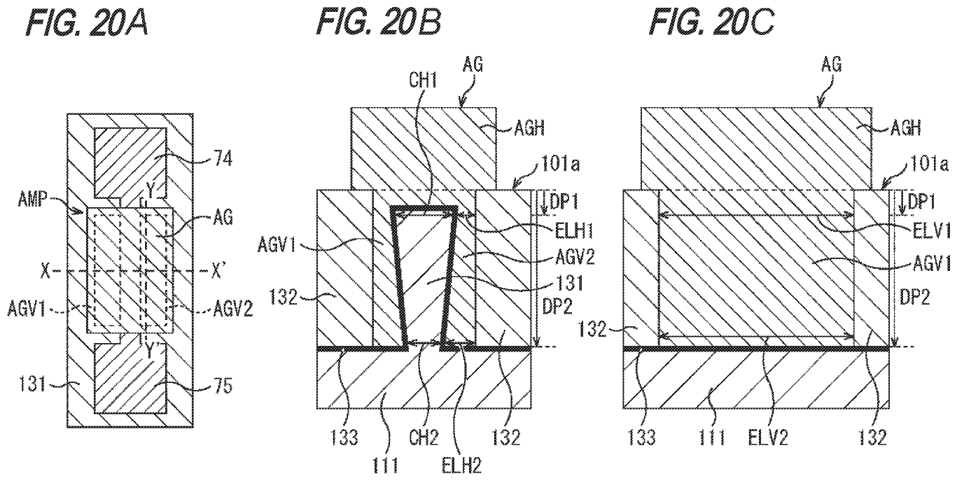

FIGS. 20A to 20C illustrate a fourth configuration example of the amplification transistor AMP.

FIG. 20A is a plan view of the amplification transistor AMP, FIG. 20B is a cross-sectional view taken along a line X-X′ of FIG. 20A, and FIG. 20C is a cross-sectional view taken along a line Y-Y′ of FIG. 20A.

In FIGS. 20A to 20C, portions corresponding to those in the above-described first to third configuration examples are denoted by the same reference numerals, and description of those portions will be omitted as appropriate.

The amplification transistor AMP according to the fourth configuration example shown in FIGS. 20A to 20C is different from that in the third configuration example shown in FIGS. 14A to 14C in shapes of the first and second vertical gate electrode portions AGV1 and AGV2 and a shape of the fin portion 131 therebetween, and the other points are common to those in the third configuration example shown in FIGS. 14A to 14C.

Specifically, in the third configuration example shown in FIGS. 14A to 14C, the side surface closer to the bottom of the fin portion 131 has a rounded shape (curved shape) in the cross-sectional view of FIG. 14B. Further, the boundary surface between the first vertical gate electrode portion AGV1 or the second vertical gate electrode portion AGV2 and the insulating film 132 is formed perpendicular to the front surface 101a (substrate surface) of the semiconductor substrate 101. Therefore, each of the first vertical gate electrode portion AGV1 and the second vertical gate electrode portion AGV2 has the cross-sectional shape in which the second electrode width ELH2 at the second depth DP2 is less than the first electrode width ELH1 at the first depth DP1.

On the other hand, in the fourth configuration example of FIGS. 20A to 20C, the fin portion 131 is formed so that the first channel width CH1 at the first depth DP1 of the fin portion 131 is longer than the second channel width CH2 at the second depth DP2, as shown in the cross-sectional view of FIG. 20B. The boundary surface between the first vertical gate electrode portion AGV1 or the second vertical gate electrode portion AGV2 and the insulating film 132 is formed perpendicular to the front surface 101a (substrate surface) of the semiconductor substrate 101. Therefore, each of the first vertical gate electrode portion AGV1 and the second vertical gate electrode portion AGV2 has a cross-sectional shape in which the second electrode width ELH2 at the second depth DP2 is greater than the first electrode width ELH1 at the first depth DP1.

In the amplification transistor AMP according to the fourth configuration example of FIGS. 20A to 20C, since a contact area between each bottom surface of the first vertical gate electrode portion AGV1 and the second vertical gate electrode portion AGV2 with the p-well 111 is larger compared to those in the above-described first to third configuration examples, a parasitic capacitance is larger than those in the first to third configuration examples.

On the other hand, in the fourth configuration example in FIGS. 20A to 20C, the bottom of the fin portion 131 forming the channel region is narrower than an upper portion. In other words, the fin portion 131 is formed such that the first channel width CH1 is longer than the second channel width CH2. Thus, by forming the bottom of the fin portion 131 narrower than the upper portion, a frontage with the p-well 111 becomes narrower, so that influence of the p-well 111 can be suppressed. Since a drain current flowing through the channel region can be increased by reducing the influence of the p-well 111, noise generated in the amplification transistor AMP can be reduced, and an SN ratio can be improved.

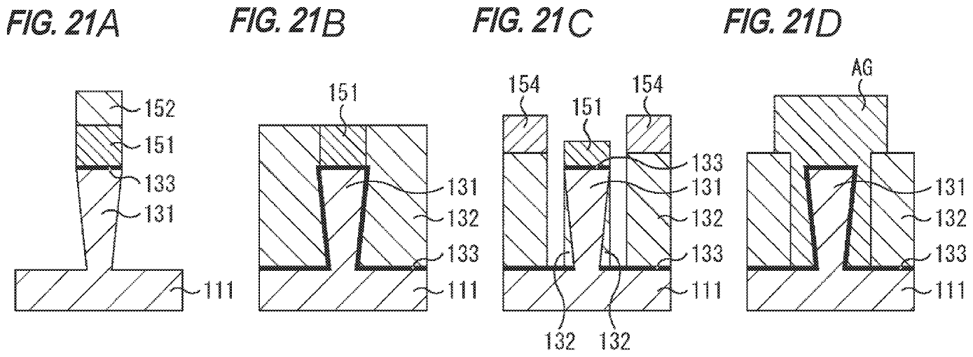

A method for forming the amplification transistor AMP according to the fourth configuration example shown in FIGS. 20A to 20C will be described with reference to FIGS. 21A to 21D.

FIGS. 21A to 21D illustrating the formation method of the fourth configuration example correspond to drawings in which some of the common steps in the formation method of the first configuration example shown in FIGS. 8A to 8D and 9A to 9D are omitted. FIG. 21A corresponds to FIG. 8C, and FIG. 21B corresponds to FIG. 9B. FIG. 21C corresponds to FIG. 9C, and FIG. 21D corresponds to FIG. 9D.

After the steps of FIGS. 8A and 8B are performed, as shown in FIG. 21A, the oxide film 133 and the p-well 111 are etched from the substrate surface to a predetermined depth using the oxide film 152 as a mask. By adjusting process conditions such as a gas type, bias voltage, power, and processing time in dry etching, as shown in FIG. 21A, the bottom of the fin portion 131 can be formed in a reverse tapered shape narrower than the upper portion.

Thereafter, as shown in FIG. 21B, the added insulating film 132 is planarized by CMP using the insulating film 151 as a stopper.

Thereafter, as shown in FIG. 21C, the insulating film 132 is etched in a direction perpendicular to the substrate surface by anisotropic etching using the patterned resist 154. When the insulating film 132 is etched perpendicularly to the substrate surface, the insulating film 132 remains on the side surface of the fin portion 131 having the reverse tapered shape, and the side surface of the fin portion 131 is protected by the insulating film 132. Therefore, interface damage on the side surface of the fin portion 131 at the time of etching can be suppressed.

Then, after the insulating film 132 remaining on the side surface of the fin portion 131 is removed and the oxide film 133 serving as a gate oxide film is formed, the insulating film 151 and the resist 154 are removed. Finally, as shown in FIG. 21D, the gate electrode AG including the first and second vertical gate electrode portions AGV1 and AGV2 is formed using, for example, a CVD method. As a material of the gate electrode AG, for example, polysilicon is used.

In the above-described steps, the step of etching the oxide film 152 and the insulating film 151 on the upper surface of the p-well 111 and the step of etching the oxide film 133 and the p-well 111 may be performed in one etching step. This is similar to the formation method of the first configuration example.

<10. Fifth Configuration Example of Amplification Transistor>

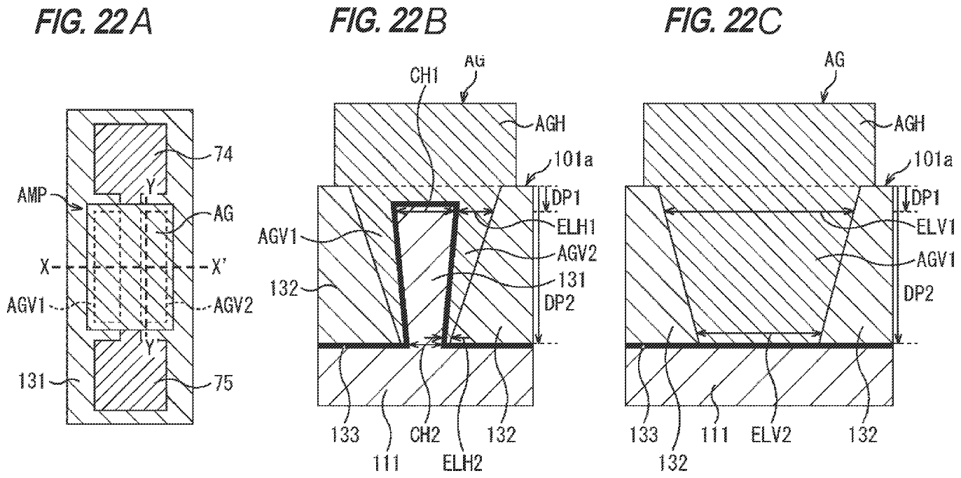

FIGS. 22A to 22C show a fifth configuration example of the amplification transistor AMP.

FIG. 22A is a plan view of the amplification transistor AMP, FIG. 22B is a cross-sectional view taken along a line X-X′ of FIG. 22A, and FIG. 22C is a cross-sectional view taken along a line Y-Y′ of FIG. 22A.

In FIGS. 22A to 22C, portions corresponding to those in the above-described first to fourth configuration examples are denoted by the same reference numerals, and description thereof will be omitted as appropriate.

The amplification transistor AMP according to the fifth configuration example shown in FIGS. 22A to 22C has the structure of the first and second vertical gate electrode portions AGV1 and AGV2 in the first configuration example shown in FIGS. 7A to 7C and the structure of the fin portion 131 in the fourth configuration example shown in FIGS. 20A to 20C.

Specifically, as for a cross-sectional shape of the fin portion 131 forming the channel region, the fifth configuration example in FIGS. 22A to 22C is similar to the fourth configuration example shown in FIGS. 20A to 20C. The fin portion 131 has a reverse tapered shape in which the bottom is narrower than the upper portion. On the other hand, regarding a cross-sectional shape of each of the first vertical gate electrode portion AGV1 and the second vertical gate electrode portion AGV2, the fifth configuration example in FIGS. 22A to 22C is similar to the first configuration example shown in FIGS. 7A to 7C. The first vertical gate electrode portion AGV1 and the second vertical gate electrode portion AGV2 each have a reverse tapered shape in which the bottom surface side of the vertical gate electrode portion AGV is narrow. Configurations other than the fin portion 131 and the vertical gate electrode portion AGV are similar to those in the first configuration example shown in FIGS. 7A to 7C and the fourth configuration example shown in FIGS. 20A to 20C.

According to the fifth configuration example of FIGS. 22A to 22C, the cross-sectional shape of each of the first and second vertical gate electrode portions AGV1 and AGV2 is the reverse tapered shape with the narrow bottom surface side, so that a parasitic capacitance can be reduced. In addition, since the cross-sectional shape of the fin portion 131 forming the channel region is the reverse tapered shape in which the bottom is narrower than the upper portion, influence of the p-well 111 can be suppressed. With such shapes of the vertical gate electrode portion AGV and the fin portion 131, noise generated in the amplification transistor AMP can be reduced, and an SN ratio can be improved.

<11. Sixth Configuration Example of Amplification Transistor>

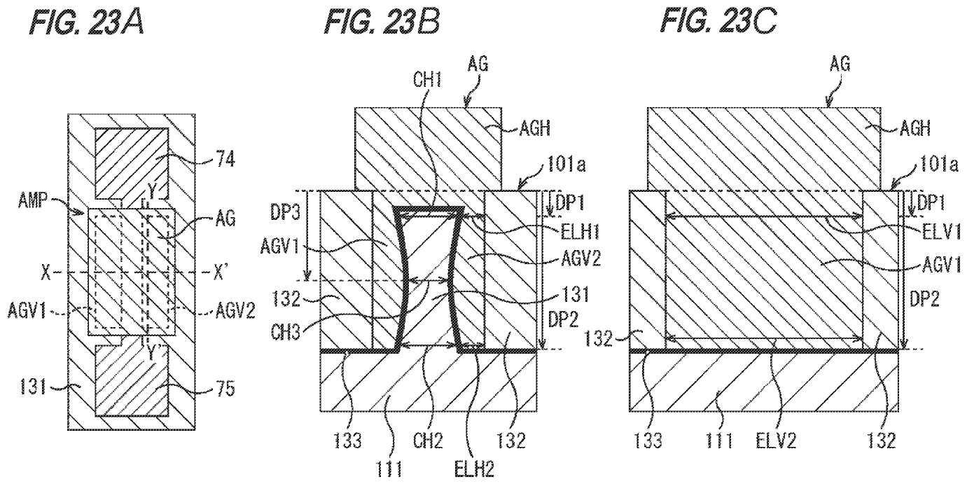

FIGS. 23A to 23C illustrate a sixth configuration example of the amplification transistor AMP.

FIG. 23A is a plan view of the amplification transistor AMP, FIG. 23B is a cross-sectional view taken along a line X-X′ of FIG. 23A, and FIG. 23C is a cross-sectional view taken along a line Y-Y′ of FIG. 23A.

In FIGS. 23A to 23C, portions corresponding to those in the above-described first to fifth configuration examples are denoted by the same reference numerals, and description thereof will be omitted as appropriate.

The amplification transistor AMP according to the sixth configuration example shown in FIGS. 23A to 23C is different from that in the third configuration example shown in FIGS. 14A to 14C in a shape of the fin portion 131, and the other points are common to those in the third configuration example shown in FIGS. 14A to 14C.

Specifically, in the third configuration example shown in FIGS. 14A to 14C, the side surface closer to the bottom of the fin portion 131 has a rounded shape in the cross-sectional view of FIG. 14B.

On the other hand, in the sixth configuration example of FIGS. 23A to 23C, the fin portion 131 has a bowing shape (bow shape) in the cross-sectional view of FIG. 23B. In other words, the fin portion 131 is formed so that a third channel width CH3 at a third depth DP3, which is an intermediate position between the first depth DP1 at the top of the fin portion 131 and the second depth DP2 at the bottom of the fin portion 131, is less than the first channel width CH1 at the first depth DP1 and is also less than the second channel width CH2 at the second depth DP2.

According to the sixth configuration example of FIGS. 23A to 23C, by forming the intermediate portion in the depth direction of the fin portion 131 narrower than the upper portion, the frontage with the p-well 111 is narrowed, so that influence of the p-well 111 can be suppressed. Since a drain current flowing through the channel region can be increased by reducing the influence of the p-well 111, noise generated in the amplification transistor AMP can be reduced, and an SN ratio can be improved.

Note that, in the sixth configuration example of FIGS. 23A to 23C, a boundary surface between the insulating film 132 and the first or second vertical gate electrode portions AGV1 or AGV2 is formed perpendicular to the front surface 101a (substrate surface). However, as in the fifth configuration example shown in FIGS. 22A to 22C, a cross-sectional shape of each of the first and second vertical gate electrode portions AGV1 and AGV2 may be a reverse tapered shape.

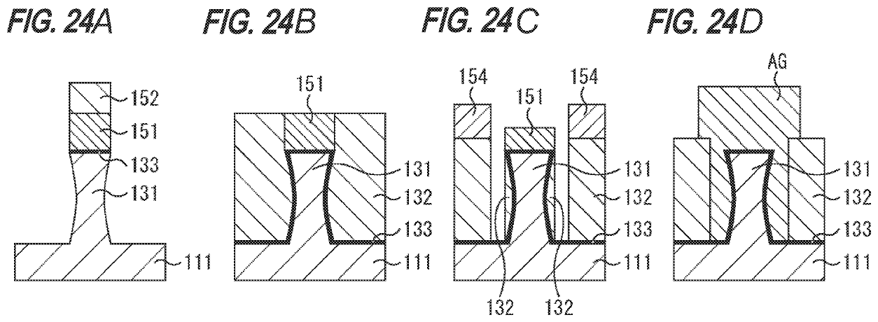

With reference to FIGS. 24A to 24D, a method for forming the amplification transistor AMP according to the sixth configuration example shown in FIGS. 23A to 23C will be described.

FIGS. 24A to 24D illustrating the formation method of the sixth configuration example correspond to drawings in which some of the common steps are omitted in the formation method of the first configuration example shown in FIGS. 8A to 8D and 9A to 9D. FIG. 24A corresponds to FIG. 8C, and FIG. 24B corresponds to FIG. 9B. FIG. 24C corresponds to FIG. 9C, and FIG. 24D corresponds to FIG. 9D.

After the steps of FIGS. 8A and 8B are performed, as shown in FIG. 24A, the oxide film 133 and the p-well 111 are etched from the substrate surface to a predetermined depth using the oxide film 152 as a mask. By adjusting process conditions such as a gas type, bias voltage, power, and processing time in dry etching, as shown in FIG. 24A, the intermediate portion of the fin portion 131 can be formed in a bowing shape narrower than the top and the bottom.

Thereafter, as shown in FIG. 24B, the added insulating film 132 is planarized by CMP using the insulating film 151 as a stopper.

Thereafter, as shown in FIG. 24C, the insulating film 132 is etched in a direction perpendicular to the substrate surface by anisotropic etching using the patterned resist 154. When the insulating film 132 is etched perpendicularly to the substrate surface, the insulating film 132 remains on the side surface of the fin portion 131 having the bowing shape, and the side surface of the fin portion 131 is protected by the insulating film 132. Therefore, interface damage on the side surface of the fin portion 131 at the time of etching can be suppressed.

Then, after the insulating film 132 on the side surface of the fin portion 131 is removed and the oxide film 133 serving as a gate oxide film is formed, the insulating film 151 and the resist 154 are removed. Finally, as shown in FIG. 24D, the gate electrode AG including the first and second vertical gate electrode portions AGV1 and AGV2 is formed by using, for example, a CVD method. As a material of the gate electrode AG, for example, polysilicon is used.

In the above-described steps, the step of etching the oxide film 152 and the insulating film 151 on the upper surface of the p-well 111 and the step of etching the oxide film 133 and the p-well 111 may be performed in one etching step. This is similar to the formation method of the first configuration example.

<12. Seventh Configuration Example of Amplification Transistor>

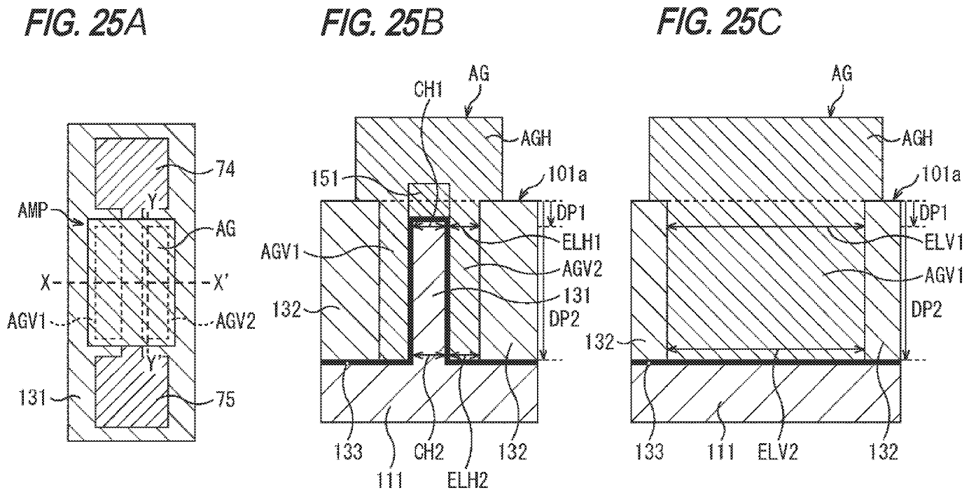

FIGS. 25A to 25C illustrate a seventh configuration example of the amplification transistor AMP.

FIG. 25A is a plan view of the amplification transistor AMP, FIG. 25B is a cross-sectional view taken along a line X-X′ of FIG. 25A, and FIG. 25C is a cross-sectional view taken along a line Y-Y′ of FIG. 25A.

In FIGS. 25A to 25C, portions corresponding to those in the above-described first to sixth configuration examples are denoted by the same reference numerals, and description thereof will be omitted as appropriate.

As for a shape of the fin portion 131, the seventh configuration example shown in FIGS. 25A to 25C is similar to the first configuration example shown in FIGS. 7A to 7C, and the first channel width CH1 at the first depth DP1 and the second channel width CH2 at the second depth DP2 are the same or substantially the same.

On the other hand, as for a shape of each of the first and second vertical gate electrode portions AGV1 and AGV2, the seventh configuration example is similar to the third configuration example shown in FIGS. 14A to 14C, and a boundary surface between the first or second vertical gate electrode portion AGV1 or AGV2 and the insulating film 132 is formed perpendicularly to the front surface 101a (substrate surface) of the semiconductor substrate 101.

In addition, an insulating film 151 other than the gate insulating film is formed between the oxide film 133 serving as the gate insulating film and (the flat electrode portion AGH of) the gate electrode AG. This insulating film 151 is arranged after the insulating film used as a hard mask is not removed in the formation methods of the above-described first to sixth configuration examples. The other points of the seventh configuration example are similar to those of the third configuration example of FIGS. 14A to 14C.

By the insulating film 151 formed on an upper surface of the fin portion 131, a drain current flowing through an upper portion of the channel region (fin portion 131) can be suppressed, and an interface state density can be reduced. Since the number of electrons (carriers) captured in the interface state is reduced, noise is reduced. Therefore, noise generated in the amplification transistor AMP can be reduced, and an SN ratio can be improved.

Note that, although not shown, a structure in which the insulating film 151 used as a hard mask is left as it is can be adopted in the amplification transistor AMP according to the above-described first to sixth configuration examples or the modifications thereof.

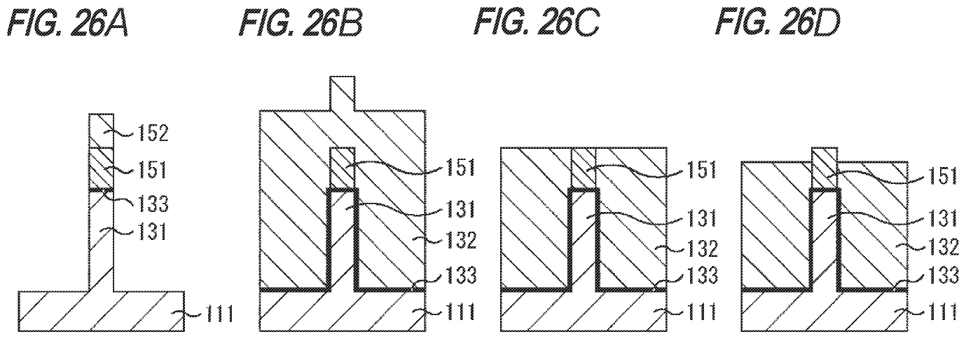

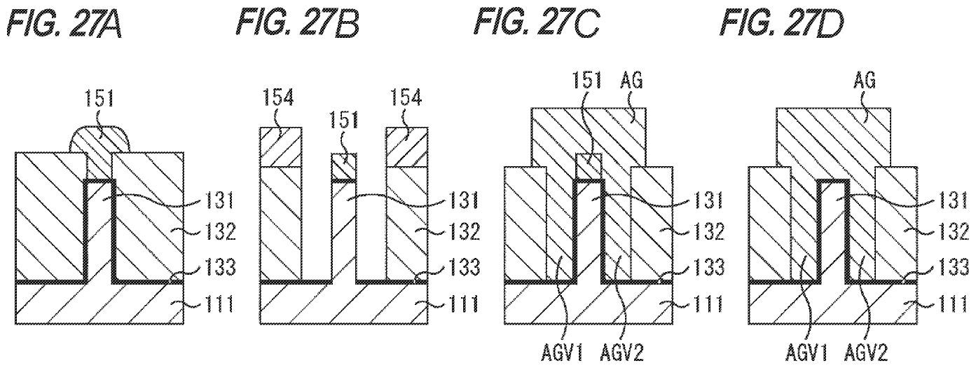

With reference to FIGS. 26A to 26D and 27A to 27D, a method for forming the amplification transistor AMP according to the seventh configuration example shown in FIGS. 25A to 25C will be described.

FIG. 26A corresponds to FIG. 8C, FIG. 26B corresponds to FIG. 9A, and FIG. 26C corresponds to FIG. 9B. Therefore, a state in FIG. 26C is formed by steps similar to the steps from FIG. 8A to FIG. 9B.

From the state shown in FIG. 26C in which the insulating film 132 and the insulating film 151 are flush with each other by CMP, the insulating film 132 is removed to a predetermined depth as shown in FIG. 26D by wet etching, for example.

Then, after the insulating film 151 is additionally formed as shown in FIG. 27A, the insulating film 132 on each side of the fin portion 131 is etched in a direction perpendicular to the substrate surface by anisotropic etching using the patterned resist 154, as shown in FIG. 27B.

Then, after the oxide film 133 is formed on the side surface of the fin portion 131, as shown in FIG. 27C, the gate electrode AG including the first and second vertical gate electrode portions AGV1 and AGV2 is formed by using a CVD method or the like while the insulating film 151 is left without being removed. As a material of the gate electrode AG, for example, polysilicon is used. By leaving the insulating film 151 without being removed, the fin portion 131 serving as the channel region can be formed in a self-aligned manner.

Alternatively, after removing the insulating film 151, the gate electrode AG including the first and second vertical gate electrode portions AGV1 and AGV2 may be formed by using the CVD method or the like. In this case, the amplification transistor AMP according to the seventh configuration example is as shown in FIG. 27D.

In the above-described steps, the step of etching the oxide film 152 and the insulating film 151 on the upper surface of the p-well 111 and the step of etching the oxide film 133 and the p-well 111 may be performed in one etching step. This is similar to the formation method of the first configuration example.

<13. Example of Use of Image Sensor>

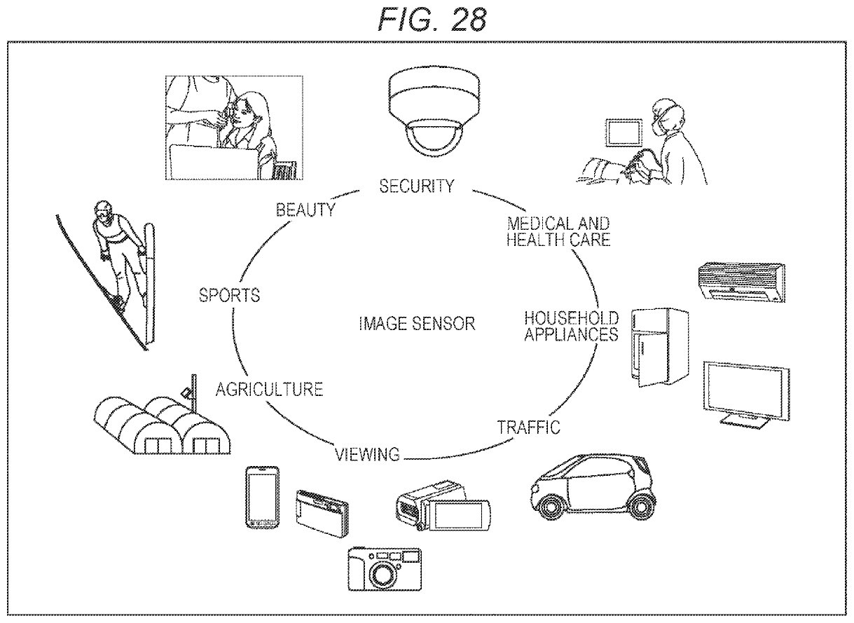

FIG. 28 is a diagram illustrating an example of use of an image sensor using the solid-state imaging device 1 described above.

An image sensor using the above-described solid-state imaging device 1 can be used, for example, in various cases for sensing light such as visible light, infrared light, ultraviolet light, and X-ray as described below.

Devices for capturing images for viewing, such as digital cameras and portable devices with camera functions

Devices used for traffic, such as in-vehicle sensors for imaging the front, back, surroundings, inside, etc. of a car for safe driving such as automatic stop, recognition of a driver's condition, or the like, surveillance cameras for monitoring running vehicles and roads, and distance measuring sensors that measure inter-vehicle distances, etc.

Devices used in household appliances such as TVs, refrigerators, air conditioners, etc., for imaging user gestures and performing device operations in accordance with the gestures

Devices used for medical and health care, such as endoscopes and devices that perform blood vessel imaging by receiving infrared light

Devices used for security, such as surveillance cameras for crime prevention and cameras for person authentication

Devices used for beauty, such as skin measuring instruments for imaging skin and microscopes for imaging scalps

Devices used for sports and the like, such as action cameras and wearable cameras for sports applications

Devices used for agriculture, such as cameras for monitoring conditions of fields and crops

<14. Example of Application to Electronic Apparatus>

The present technology is not limited to application to a solid-state imaging device. In other words, the present technology is applicable to entire electronic apparatus using a solid-state imaging device for an image capturing unit (a photoelectric conversion unit), such as an imaging apparatus such as a digital still camera or a video camera, a portable terminal apparatus having an imaging function, and a copying machine using a solid-state imaging device for an image capturing unit. The solid-state imaging device may be formed as a single chip, or may be formed as a module having an imaging function in which an imaging unit and a signal processing unit or an optical system are packaged together.

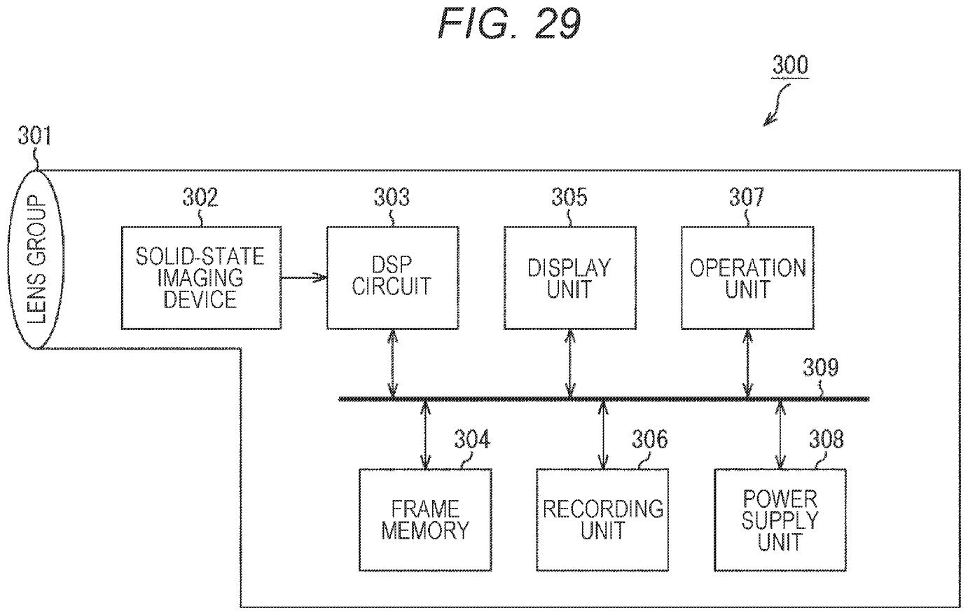

FIG. 29 is a block diagram illustrating a configuration example of an imaging apparatus as an electronic apparatus to which the present technology is applied.

An imaging apparatus 300 in FIG. 29 includes an optical unit 301 including a lens group and the like, a solid-state imaging device (imaging device) 302 adopting a configuration of the solid-state imaging device 1 in FIG. 1, and a digital signal processor (DSP) circuit 303 that is a camera signal processing circuit. Further, the imaging apparatus 300 also includes a frame memory 304, a display unit 305, a recording unit 306, an operation unit 307, and a power supply unit 308. The DSP circuit 303, the frame memory 304, the display unit 305, the recording unit 306, the operation unit 307, and the power supply unit 308 are mutually connected via a bus line 309.

The optical unit 301 captures incident light (image light) from a subject and forms an image on an imaging surface of the solid-state imaging device 302. The solid-state imaging device 302 converts an amount of incident light formed on the imaging surface by the optical unit 301 into an electric signal in pixel units and outputs the electric signal as a pixel signal. As this solid-state imaging device 302, the solid-state imaging device 1 in FIG. 1 can be used. In other words, the solid-state imaging device includes, in the pixel circuit, the amplification transistor AMP having the FinFET structure in which the fin portion 131 forming the channel region is sandwiched between the first vertical gate electrode portion AGV1 and the second vertical gate electrode portion AGV2.

The display unit 305 includes, for example, a thin display such as a liquid crystal display (LCD) or an organic electro luminescence (EL) display, and displays a moving image or a still image captured by the solid-state imaging device 302. The recording unit 306 records a moving image or a still image captured by the solid-state imaging device 302 on a recording medium such as a hard disk or a semiconductor memory.

The operation unit 307 issues an operation command for various functions of the imaging apparatus 300 under an operation of a user. The power supply unit 308 appropriately supplies various power supplies serving as operation power supplies for the DSP circuit 303, the frame memory 304, the display unit 305, the recording unit 306, and the operation unit 307 to these supply targets.

As described above, by using the solid-state imaging device 1 having the amplification transistor AMP according to the first to seventh configuration examples or the modifications thereof described above as the solid-state imaging device 302, noise of a pixel signal to be output is reduced, and an SN ratio can be improved. Therefore, in the imaging apparatus 300 such as a video camera, a digital still camera, and a camera module for a mobile device such as a mobile phone, quality of a captured image can be improved.

In the above-described examples, the solid-state imaging device in which a first conductivity type is a P-type, a second conductivity type is an N-type, and electrons are signal charges has been described. However, the present technology can also be applied to a solid-state imaging device in which holes are signal charges. In other words, the first conductivity type is the N-type, the second conductivity type is the P-type, and each of the semiconductor regions described above can be configured by a semiconductor region of the opposite conductivity type.

In addition, the present technology is not limited to application to a solid-state imaging device that detects a distribution of an amount of incident light of visible light and captures it as an image. It can be applied to a solid-state imaging device that detects a distribution of an amount of incident light of infrared light, X-ray, particles, or the like and captures it as an image and, in a broad sense, an entire solid-state imaging device (a physical amount distribution detection device) such as a fingerprint detection sensor that detects a distribution of other physical quantities such as pressure and electrostatic capacitance and captures it as an image.

Further, the present technology is not limited to the solid-state imaging device, and is applicable to a general semiconductor device having another semiconductor integrated circuit.

It should be noted that the effects described in the present specification are merely examples and are not limited, and effects other than those described in the present specification may be provided.

Note that the present technology can have the following configurations.

(1)

A solid-state imaging device including:

an amplification transistor having a gate electrode including first and second vertical gate electrode portions embedded in a depth direction from a substrate surface of a semiconductor substrate,

in which the first vertical gate electrode portion and the second vertical gate electrode portion each have a structure so that a second electrode width at a second depth from the substrate surface is shorter than a first electrode width at a first depth from the substrate surface,

the first depth is a position of a channel top surface closest to the substrate surface of a channel region between the first vertical gate electrode portion and the second vertical gate electrode portion,

the second depth is a position of a vertical gate electrode portion bottom surface farthest from the substrate surface of the first vertical gate electrode portion and the second vertical gate electrode portion, and

directions of the first electrode width and the second electrode width are the same as a direction of a channel width of the channel region.

(2)

The solid-state imaging device according to (1), in which

a first channel width of the channel region at the first depth is shorter than a second channel width of the channel region at the second depth.

(3)

The solid-state imaging device according to (2), in which

in a cross-sectional view, a side surface closer to a bottom of the channel region far from the substrate surface has a curved shape.

(4)

The solid-state imaging device according to (1), in which

a first channel width of the channel region at the first depth and a second channel width of the channel region at the second depth are the same or substantially the same.

(5)

The solid-state imaging device according to (1), in which

a first channel width of the channel region at the first depth is longer than a second channel width of the channel region at the second depth.

(6)

The solid-state imaging device according to (1), in which

a channel width at a third depth, that is an intermediate position between the first depth and the second depth, is shorter than a channel width at the first depth.

(7)

The solid-state imaging device according to (6), in which

the channel width at the third depth is also shorter than a channel width at the second depth.

(8)

The solid-state imaging device according to any one of (1) to (7), in which

the first vertical gate electrode portion and the second vertical gate electrode portion each have a reverse tapered shape in which the vertical gate electrode portion bottom surface side is narrow in the cross-sectional view.

(9)

The solid-state imaging device according to any one of (1) to (8), in which

the first vertical gate electrode portion and the second vertical gate electrode portion each have a sub-trench in which an inner side wall on the channel region side is dug to a position deeper than an outer side wall in the cross-sectional view.

(10)

The solid-state imaging device according to any one of (1) to (9), in which

the amplification transistor has an insulating film other than a gate insulating film between the channel top surface of the channel region and the gate electrode.

(11)

The solid-state imaging device according to any one of (1) to (10), in which

a plane shape including the first vertical gate electrode portion and the second vertical gate electrode portion is rectangular.

(12)

The solid-state imaging device according to any one of (1) to (10), in which

a plane shape including the first vertical gate electrode portion and the second vertical gate electrode portion is elliptical.

(13)

A method for manufacturing a solid-state imaging device, including:

forming, as a part of a gate electrode of an amplification transistor, a first and second vertical gate electrode portions embedded in a depth direction from a substrate surface of a semiconductor substrate,
in which the first vertical gate electrode portion and the second vertical gate electrode portion each have a structure so that a second electrode width at a second depth from the substrate surface is shorter than a first electrode width at a first depth from the substrate surface,
the first depth is a position of a channel top surface closest to the substrate surface of a channel region between the first vertical gate electrode portion and the second vertical gate electrode portion,
the second depth is a position of a vertical gate electrode portion bottom surface farthest from the substrate surface of the first vertical gate electrode portion and the second vertical gate electrode portion, and
directions of the first electrode width and the second electrode width are the same as a direction of a channel width of the channel region.

(14)

An electronic apparatus including:

a solid-state imaging device provided with
an amplification transistor having a gate electrode including first and second vertical gate electrode portions embedded in a depth direction from a substrate surface of a semiconductor substrate,
in which the first vertical gate electrode portion and the second vertical gate electrode portion each have a structure so that a second electrode width at a second depth from the substrate surface is shorter than a first electrode width at a first depth from the substrate surface,
the first depth is a position of a channel top surface closest to the substrate surface of a channel region between the first vertical gate electrode portion and the second vertical gate electrode portion,
the second depth is a position of a vertical gate electrode portion bottom surface farthest from the substrate surface of the first vertical gate electrode portion and the second vertical gate electrode portion, and
directions of the first electrode width and the second electrode width are the same as a direction of a channel width of the channel region.

(15)

A solid-state imaging device, comprising:

a semiconductor substrate; and
a gate electrode, wherein the gate electrode includes first and second vertical gate electrode portions embedded in a depth direction from a first surface of the semiconductor substrate, and wherein a width of the first vertical gate electrode portion and a width of the second vertical gate electrode portion varies with a distance from the first surface.

(16)

The solid-state imaging device according to (15), wherein the first and second vertical gate electrode portions extend from a flat electrode portion.

(17)

The solid-state imaging device according to (15) or (16), wherein a fin portion forming a channel region of a transistor is between the first and second vertical gate electrode portions, and wherein a direction of the width of the first vertical gate electrode portion and a direction of the width of the second vertical gate electrode portion are the same as a direction of a channel width of the channel region.

(18)

The solid-state imaging device according to (16) or (17), and wherein the flat electrode portion is on the first surface side of the semiconductor substrate.

(19)

The solid-state imaging device according to any one of (16) to (18), wherein the width of the first vertical gate electrode portion and the width of the second vertical gate electrode portion decrease with distance from the flat electrode portion.

(20)

The solid-state imaging device according to (19), wherein the width of the first vertical gate electrode portion and the width of the second vertical gate electrode portion decrease linearly with distance from the flat electrode portion.

(21)

The solid-state imaging device according to any one of (16) to (18), wherein the width of the first vertical gate electrode portion and the width of the second vertical gate electrode portion increase with distance from the flat electrode portion.

(22)

The solid-state imaging device according to (21), wherein the width of the first vertical gate electrode portion and the width of the second vertical gate electrode portion increase linearly with distance from the flat electrode portion.

(23)

The solid-state imaging device according to any one of (16) to (18), wherein the width of the first vertical gate electrode portion and the width of the second vertical gate electrode portion is widened at a point between ends of the vertical gate electrode portions adjacent the flat electrode portion and ends of the vertical gate electrode portions farthest from the flat electrode portion.

(24)

The solid-state imaging device according to (23), wherein a fin portion forming a channel region of a transistor is between the first and second vertical gate electrode portions, and wherein an intermediate portion of the fin portion in a depth direction is narrower than an upper portion of the fin portion.

(25)

The solid-state imaging device according to (17), wherein a base portion of the fin portion is rounded.

(26)

The solid-state imaging device according to (25), wherein the width of the first vertical gate electrode portion and the width of the second vertical gate electrode portion decrease with distance from the flat electrode portion.

(27)

The solid-state imaging device according to (25) or (26), wherein a top portion of the fin portion is rounded.

(28)

The solid-state imaging device according to (17), wherein a sub-trench is formed along each side of a base portion of the fin portion.

(29)

The solid-state imaging device according to (28), wherein the width of the first vertical gate electrode portion and the width of the second vertical gate electrode portion decrease with distance from the flat electrode portion.

(30)

The solid-state imaging device according to any one of (16) to (29), wherein the flat electrode portion is rectangular in a plan view.

(31)

The solid-state imaging device according to any one of (16) to (29), wherein the flat electrode portion is elliptical in a plan view.

(32)

The solid-state imaging device according to any one of (17) to (31), further comprising:

an insulating film disposed on a top of the fin portion.

(33)

A solid-state imaging device, comprising:

a semiconductor substrate;
a gate electrode, including:
a flat electrode portion;
a first vertical gate electrode portion;
a second vertical gate electrode portion;
a fin portion between the first and second vertical gate electrode portions, wherein a width of the first vertical gate electrode portion and a width of the second vertical gate electrode portion decrease with distance from the flat electrode portion, wherein the fin portion forms a channel region, and wherein side surfaces of the fin portion are parallel to one another.

(34)

A solid-state imaging device, comprising:

a semiconductor substrate;
a gate electrode, including:
a flat electrode portion;
a first vertical gate electrode portion;
a second vertical gate electrode portion;
a fin portion between the first and second vertical gate electrode portions, wherein a width of the first vertical gate electrode portion and a width of the second vertical gate electrode portion increase with distance from the flat electrode portion, wherein the fin portion forms a channel region, and wherein side surfaces of the fin portion are nonparallel to one another.

(35)

A solid-state imaging device, comprising:

a semiconductor substrate;
a gate electrode, including:
a flat electrode portion;
a first vertical gate electrode portion;
a second vertical gate electrode portion;
a fin portion between the first and second vertical gate electrode portions, wherein a width of the first vertical gate electrode portion and a width of the second vertical gate electrode portion vary with distance from the flat electrode portion, wherein the fin portion forms a channel region, and wherein the fin portion is narrower in an intermediate portion in a depth direction.

(36)

A solid-state imaging device, comprising:

a semiconductor substrate;
a gate electrode, including:
a flat electrode portion;
a first vertical gate electrode portion;
a second vertical gate electrode portion;
a fin portion between the first and second vertical gate electrode portions, wherein a width of the first vertical gate electrode portion and a width of the second vertical gate electrode portion decreases with distance from the flat electrode portion, wherein the fin portion forms a channel region, and wherein base portions of the fin portion are rounded.

It should be understood by those skilled in the art that various modifications, combinations, sub-combinations and alterations may occur depending on design requirements and other factors insofar as they are within the scope of the appended claims or the equivalents thereof.

### REFERENCE SIGNS LIST

1 Solid-state imaging device
10 First substrate
11 First semiconductor substrate
12 Sensor pixel
20 Second substrate
21 Second semiconductor substrate
22 Readout circuit
30 Third substrate
101 Semiconductor substrate
131 Fin portion
132 Insulating film
133 Oxide film
151 Insulating film
AMP Amplification transistor
AG Gate electrode
AGV1 First vertical gate electrode portion
AGV2 Second vertical gate electrode portion
CH1 First channel width
CH2 Second channel width
CH3 Third channel width
DP1 First depth
DP2 Second depth
DP3 Third depth
ELH1 First electrode width
ELH2 Second electrode width
ELV1 First electrode width
ELV2 Second electrode width
300 Imaging apparatus
302 Solid-state imaging device

What is claimed is:

1. A solid-state imaging device, comprising:
a semiconductor substrate; and
a gate electrode, wherein the gate electrode includes first and second vertical gate electrode portions embedded in a depth direction from a first surface of the semiconductor substrate, and wherein a width of the first vertical gate electrode portion and a width of the second vertical gate electrode portion varies with a distance from the first surface.

2. The solid-state imaging device according to claim 1, wherein the first and second vertical gate electrode portions extend from a flat electrode portion.

3. The solid-state imaging device according to claim 2, wherein a fin portion forming a channel region of a transistor is between the first and second vertical gate electrode portions, and wherein a direction of the width of the first vertical gate electrode portion and a direction of the width of the second vertical gate electrode portion are the same as a direction of a channel width of the channel region.

4. The solid-state imaging device according to claim 3, and wherein the flat electrode portion is on the first surface side of the semiconductor substrate.

5. The solid-state imaging device according to claim 2, wherein the width of the first vertical gate electrode portion and the width of the second vertical gate electrode portion decrease with distance from the flat electrode portion.

6. The solid-state imaging device according to claim 5, wherein the width of the first vertical gate electrode portion and the width of the second vertical gate electrode portion decrease linearly with distance from the flat electrode portion.

7. The solid-state imaging device according to claim 2, wherein the width of the first vertical gate electrode portion and the width of the second vertical gate electrode portion increase with distance from the flat electrode portion.

8. The solid-state imaging device according to claim 7, wherein the width of the first vertical gate electrode portion and the width of the second vertical gate electrode portion increase linearly with distance from the flat electrode portion.

9. The solid-state imaging device according to claim 2, wherein the width of the first vertical gate electrode portion and the width of the second vertical gate electrode portion is widened at a point between ends of the vertical gate electrode portions adjacent the flat electrode portion and ends of the vertical gate electrode portions farthest from the flat electrode portion.

10. The solid-state imaging device according to claim 9, wherein a fin portion forming a channel region of a transistor is between the first and second vertical gate electrode portions, and wherein an intermediate portion of the fin portion in a depth direction is narrower than an upper portion of the fin portion.

11. The solid-state imaging device according to claim 3, wherein a base portion of the fin portion is rounded.

12. The solid-state imaging device according to claim 11, wherein the width of the first vertical gate electrode portion and the width of the second vertical gate electrode portion decrease with distance from the flat electrode portion.

13. The solid-state imaging device according to claim 11, wherein a top portion of the fin portion is rounded.

14. The solid-state imaging device according to claim 3, wherein a sub-trench is formed along each side of a base portion of the fin portion.

15. The solid-state imaging device according to claim 14, wherein the width of the first vertical gate electrode portion and the width of the second vertical gate electrode portion decrease with distance from the flat electrode portion.

16. The solid-state imaging device according to claim 2, wherein the flat electrode portion is rectangular in a plan view.

17. The solid-state imaging device according to claim 2, wherein the flat electrode portion is elliptical in a plan view.

18. The solid-state imaging device according to claim 3, further comprising:
an insulating film disposed on a top of the fin portion.

19. A solid-state imaging device, comprising:
a semiconductor substrate;
a gate electrode, including:
a flat electrode portion;
a first vertical gate electrode portion;
a second vertical gate electrode portion;
a fin portion between the first and second vertical gate electrode portions, wherein a width of the first vertical gate electrode portion and a width of the second vertical gate electrode portion decrease with distance from the flat electrode portion, wherein the fin portion forms a channel region, and wherein side surfaces of the fin portion are parallel to one another.

20. A solid-state imaging device, comprising:
a semiconductor substrate;
a gate electrode, including:
a flat electrode portion;
a first vertical gate electrode portion;
a second vertical gate electrode portion;
a fin portion between the first and second vertical gate electrode portions, wherein a width of the first vertical gate electrode portion and a width of the second vertical gate electrode portion increase with distance from the flat electrode portion, wherein the fin portion forms a channel region, and wherein side surfaces of the fin portion are nonparallel to one another.

21. A solid-state imaging device, comprising:
a semiconductor substrate;
a gate electrode, including:
a flat electrode portion;
a first vertical gate electrode portion;
a second vertical gate electrode portion;
a fin portion between the first and second vertical gate electrode portions, wherein
a width of the first vertical gate electrode portion and a width of the second vertical gate electrode portion vary with distance from the flat electrode portion, wherein the fin portion forms a channel region, and wherein the fin portion is narrower in an intermediate portion in a depth direction.

22. A solid-state imaging device, comprising:
a semiconductor substrate;
a gate electrode, including:
a flat electrode portion;
a first vertical gate electrode portion;
a second vertical gate electrode portion;
a fin portion between the first and second vertical gate electrode portions, wherein a width of the first vertical gate electrode portion and a width of the second vertical gate electrode portion decreases with distance from the flat electrode portion, wherein the fin portion forms a channel region, and wherein base portions of the fin portion are rounded.
